(19) United States
(12) Patent Application Publication
(10) Pub. No.: US 2025/0200678 A1
(43) Pub. Date: Jun. 19, 2025

(54) ELECTRONIC APPARATUS AND CONTROLLING METHOD THEREOF

(71) Applicant: Samsung Electronics Co., Ltd., Suwon-si (KR)

(72) Inventors: Jooyoo KIM, Suwon-si (KR); Yoobin BAE, Suwon-si (KR); Hyungseon SONG, Suwon-si (KR); Hyoungsang CHO, Suwon-si (KR); Minjung SOHN, Suwon-si (KR)

(21) Appl. No.: 18/984,363

(22) Filed: Dec. 17, 2024

Related U.S. Application Data
(63) Continuation of application No. PCT/KR2023/001767, filed on Feb. 8, 2023.

(30) Foreign Application Priority Data
Sep. 1, 2022 (KR) 10-2022-0110792
Nov. 9, 2022 (KR) 10-2022-0148767

(51) Int. Cl. G06Q 50/06; G01R 11/56; H02J 3/00

(52) U.S. Cl. CPC G06Q 50/06; G01R 11/56; H02J 3/003; H02J 2203/20

(57) ABSTRACT

An electronic apparatus is provided. The electronic apparatus includes memory including one or more storage media storing instructions and a preset period for measuring electrical energy, and one or more processors communicatively coupled to the memory, wherein the instructions, when executed by the one or more processors individually or collectively, cause the electronic apparatus to, based on an electrical energy prediction command being received, acquire collected electrical energy from a start time of a preset period to a time when the electrical energy command is received, acquire predicted electrical energy corresponding to the preset period based on the collected electrical energy, based on the predicted electrical energy exceeding target electrical energy, acquire a number of remaining days from a time when the electrical energy prediction command is received to a time when the preset period ends, acquire a first number of operating days for which the electronic apparatus operates in a normal mode and a second number of operating days for which the electronic apparatus operates in a power-saving mode based on the collected electrical energy, the target electrical energy and the number of remaining days, generate schedule information such that the electronic apparatus operates in a power-saving mode for the second operating days during the remaining period, and determine an operation mode of the electronic apparatus based on the schedule information.

### CROSS-REFERENCE TO RELATED APPLICATION(S)

This application is a continuation application, claiming priority under § 365 (c), of an International application No. PCT/KR2023/001767, filed on Feb. 8, 2023, which is based on and claims the benefit of a Korean patent application number 10-2022-0110792, filed on Sep. 1, 2022, in the Korean Intellectual Property Office, and of a Korean patent application number 10-2022-0148767, filed on Nov. 9, 2022, in the Korean Intellectual Property Office, the disclosure of each of which is incorporated by reference herein in its entirety.

### BACKGROUND

### 1. Field

The disclosure relates to an electronic apparatus and a controlling method thereof. More particularly, the disclosure relates to an electronic apparatus that manages electrical energy considering target electrical energy and a controlling method thereof.

### 2. Description of Related Art

When measuring electrical energy consumed in a home, it is possible to figure out the total amount of electrical energy consumed for a certain period. Based on the measured electrical energy, a user may determine whether to save electrical energy.

If it is expected that the measured electrical energy exceeds the target electrical energy, the user may control an apparatus to operate in a power-saving mode. However, it may be difficult for the user to determine whether the target electrical energy will be exceeded based solely on the currently measured electrical energy.

When measuring electrical energy, it is possible to calculate the electricity bill based on the electrical energy consumed during a certain period. If there is a progressive tax for electricity bills based on the amount of electrical energy, the user may want to consume electricity without paying the progressive tax. However, if the user directly determines the measured electrical energy in real time and performs the power-saving mode, it may cause inconvenience to the user.

If the power-saving mode is used for a long time simply to reduce the electrical energy, the performance of the apparatus itself may decrease. As a result, the user may experience less satisfaction with the use of the apparatus.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an electronic apparatus that generates schedule information indicating a time of performing a power-saving mode based on target electrical energy and operates based on the schedule information and a controlling method thereof.

Additional aspects will be set forth in part in the description which follows and, in part, will be apparent from the description, or may be learned by practice of the presented embodiments.

In accordance with an aspect of the disclosure, an electronic apparatus is provided. The electronic apparatus includes memory including one or more storage media storing instructions and a preset period for measuring electrical energy, and one or more processors communicatively coupled to the memory, wherein the instructions, when executed by the one or more processors individually or collectively, cause the electronic apparatus to, based on an electrical energy prediction command being received, acquire collected electrical energy from a start time of a preset period to a time when the electrical energy command is received, acquire predicted electrical energy corresponding to the preset period based on the collected electrical energy, based on the predicted electrical energy exceeding target electrical energy, acquire a number of remaining days from a time when the electrical energy prediction command is received to a time when the preset period ends, acquire a first number of operating days for which the electronic apparatus operates in a normal mode and a second number of operating days for which the electronic apparatus operates in a power-saving mode based on the collected electrical energy, the target electrical energy and the number of remaining days, generate schedule information such that the electronic apparatus operates in a power-saving mode for the second operating days during the remaining period, and determine an operation mode of the electronic apparatus based on the schedule information.

In accordance with another aspect of the disclosure, a controlling method performed by an electronic apparatus that stores in memory of the electronic apparatus a preset period for measuring electrical energy is provided. The method includes, based on an electrical energy prediction command being received, acquiring collected electrical energy from a start time of a preset period to a time when the electrical energy prediction command is received, acquiring predicted electrical energy corresponding to the preset period based on the collected electrical energy, based on the predicted electrical energy exceeding target electrical energy, acquiring a number of remaining days from a time when the electrical energy prediction command is received to a time when the preset period ends, acquiring a first number of operating days for which the electronic apparatus operates in a normal mode and a second number of operating days for which the electronic apparatus operates in a power-saving mode based on the collected electrical energy, the target electrical energy and the number of remaining days, generating schedule information such that the electronic apparatus operates in a power-saving mode for the second operating days during the remaining period, and determining an operation mode of the electronic apparatus based on the schedule information.

One or more non-transitory computer-readable storage media storing one or more computer programs including computer-executable instructions that, when executed by one or more processors of an electronic device individually or collectively, cause the electronic device to perform operations are provided. The operations include based on an electrical energy prediction command being received, acquiring collected electrical energy from a start time of a preset period to a time when the electrical energy prediction command is received, acquiring predicted electrical energy corresponding to the preset period based on the collected electrical energy, based on the predicted electrical energy exceeding target electrical energy, acquiring a number of remaining days from a time when the electrical energy prediction command is received to a time when the preset period ends, acquiring a first number of operating days for which the electronic apparatus operates in a normal mode and a second number of operating days for which the electronic apparatus operates in a power-saving mode based on the collected electrical energy, the target electrical energy and the number of remaining days, generating schedule information such that the electronic apparatus operates in a power-saving mode for the second operating days during the remaining period, and determining an operation mode of the electronic apparatus based on the schedule information.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an electronic apparatus according to an embodiment of the disclosure;

FIG. 2 is a block diagram illustrating specific configuration of the electronic apparatus in FIG. 1 according to an embodiment of the disclosure;

FIG. 3 is a view provided to explain an electrical energy management system according to an embodiment of the disclosure;

FIG. 4 is a view provided to explain an electrical energy management system according to an embodiment of the disclosure;

FIG. 5 is a flowchart provided to explain an operation of receiving a user input through an electrical energy management application according to an embodiment of the disclosure;

FIG. 6 is a flowchart provided to explain an operation of performing a power-saving mode by comparing target electrical energy with predicted electrical energy according to an embodiment of the disclosure;

FIG. 7 is a flowchart provided to explain an operation of receiving electrical energy directly from a user according to an embodiment of the disclosure;

FIG. 8 is a view provided to explain an operation of receiving electrical energy directly from a user according to an embodiment of the disclosure;

FIG. 9 is a flowchart provided to explain an operation of receiving electrical energy from an external server according to an embodiment of the disclosure;

FIG. 10 is a flowchart provided to explain an operation of calculating a start time of a power-saving mode according to an embodiment of the disclosure;

FIG. 11 is a flowchart provided to explain an operation of calculating a start time of a power-saving mode according to an embodiment of the disclosure;

FIG. 12 is a view provided to explain an operation of calculating predicted electrical energy based on electrical energy collected at a present time according to an embodiment of the disclosure;

FIG. 13 is a view provided to explain an operation of calculating predicted electrical energy by considering performance of a power-saving mode according to an embodiment of the disclosure;

FIG. 14 is a view provided to explain an operation of calculating predicted electrical energy by considering performance of a power-saving mode according to an embodiment of the disclosure;

FIG. 15 is a view provided to explain an operation of determining a start time of a power-saving mode to be a present time according to an embodiment of the disclosure;

FIG. 16 is a view provided to explain an operation of determining a start time of a power-saving mode to be a future time according to an embodiment of the disclosure;

FIG. 17 is a view provided to explain a process of calculating a number of operating days in a power-saving mode according to an embodiment of the disclosure;

FIG. 18 is a view provided to explain a process of calculating a number of operating days in a power-saving mode according to an embodiment of the disclosure;

FIG. 19 is a view provided to explain a process of calculating a number of operating days a power-saving mode according to an embodiment of the disclosure;

FIG. 20 is a view provided to explain a screen for acquiring electrical energy according to an embodiment of the disclosure;

FIG. 21 is a view provided to explain a screen indicating collected electrical energy and a progressive tax section according to an embodiment of the disclosure;

FIG. 22 is a view provided to explain a screen indicating consumed electrical energy and saved electrical energy according to an embodiment of the disclosure;

FIG. 23 is a view provided to explain a screen indicating information related to a power-saving mode according to an embodiment of the disclosure;

FIG. 24 is a view provided to explain a screen indicating information related to a power-saving mode according to an embodiment of the disclosure;

FIG. 25 is a view provided to explain a screen indicating consumed electrical energy for each device according to an embodiment of the disclosure;

FIG. 26 is a view provided to explain a screen for a blind automatic control operation according to an embodiment of the disclosure;

FIG. 27 is a view provided to explain that a screen indicating electrical energy varies by country according to an embodiment of the disclosure;

FIG. 28 is a view provided to explain a screen indicating information related to consumed electrical energy and predicted electrical energy according to an embodiment of the disclosure;

FIG. 29 is a view provided to explain an operation of performing a power-saving mode by considering electrical energy for a plurality of devices according to an embodiment of the disclosure; and

FIG. 30 is a view provided to explain a controlling method of an electronic apparatus according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

General terms that are currently widely used are selected as the terms used in the embodiments of the disclosure in consideration of their functions in the disclosure, but may be changed based on the intention of those skilled in the art or a judicial precedent, the emergence of a new technique, or the like. In addition, in a specific case, terms arbitrarily chosen by an applicant may exist, in which case, the meanings of such terms will be described in detail in the corresponding descriptions of the disclosure. Therefore, the terms used in the embodiments of the disclosure need to be defined on the basis of the meanings of the terms and the overall contents throughout the disclosure rather than simple names of the terms.

In the disclosure, the expressions “have,” “may have,” “include” or “may include” indicate existence of corresponding features (e.g., components such as numeric values, functions, operations, or components), but do not exclude presence of additional features.

An expression, “at least one of A or/and B” should be understood as indicating any one of “A,” “B,” and “both of A and B.”

Expressions “first,” “second,” “1st,” “2nd,” or the like, used in the disclosure may indicate various components regardless of sequence and/or importance of the components, will be used only in order to distinguish one component from the other components, and do not limit the corresponding components.

When it is described that an element (e.g., a first element) is referred to as being “(operatively or communicatively) coupled with/to” or “connected to” another element (e.g., a second element), it should be understood that it may be directly coupled with/to or connected to the other element, or they may be coupled with/to or connected to each other through an intervening element (e.g., a third element).

In this specification, terms such as “comprise” or “have” are intended to designate the presence of features, numbers, steps, operations, components, parts, or a combination thereof described in the specification, but are not intended to exclude in advance the possibility of the presence or addition of one or more of other features, numbers, steps, operations, components, parts, or a combination thereof.

In various embodiments, a “module” or a “unit” may perform at least one function or operation, and be implemented as hardware or software or be implemented as a combination of hardware and software. In addition, a plurality of “modules” or a plurality of “units” may be integrated into at least one module and be implemented as one or more processors (not shown) except for a ‘module’ or a ‘unit’ that needs to be implemented as specific hardware.

In this specification, a term ‘user’ may refer to a person using an electronic apparatus or a device using an electronic apparatus (e.g., an artificial intelligence electronic apparatus).

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

Hereinafter, an embodiment of the disclosure will be described in greater detail with reference to the accompanying drawings.

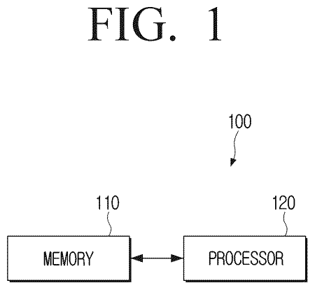

FIG. 1 is a block diagram illustrating an electronic apparatus according to an embodiment of the disclosure.

Referring to FIG. 1, an electronic apparatus 100 may include at least one of memory 110 or one or more processors 120.

The electronic apparatus 100 according to various embodiments may include at least one of, for example, a smartphone, a tablet personal computer (PC), a mobile phone, a desktop PC, a laptop PC, a personal digital assistant (PDA), or a portable multimedia player (PMP). In some embodiments, the electronic apparatus 100 may include at least one of, for example, a television, a digital versatile disc (DVD) player, or a media box (e.g., Samsung HomeSync™, Apple TV™, or Google TV™).

The memory 110 may store a preset period for measuring electrical energy. The preset period may represent a unit of time over which electrical energy is accumulated and managed (or calculated). The preset period may be one of days, weeks, months, or years. For example, when the preset period is a month, the electronic apparatus 100 may measure and manage electrical energy on a monthly basis. The electrical energy collected during January may be 300 kWh, and the electrical energy collected during February may be 250 kWh. A user may predetermine the preset period through an electrical energy management application included in the electronic apparatus 100. In addition, the electronic apparatus 100 may store the preset period set by the user in the memory 110.

Upon receiving an electrical energy prediction command, the one or more processors 120 may acquire collected electrical energy from the time when the preset period starts to the time when the electrical energy prediction command is received, acquire predicted electrical energy corresponding to the preset period based on the collected electrical energy, and, when the predicted electrical energy exceeds target electrical energy, acquire the number of remaining days from the time when the electrical energy prediction command is received to the time when the preset period ends, acquire a first number of operating days in which the electronic apparatus 100 operates in a normal mode and a second number of days in which the electronic apparatus 100 operates in a power-saving mode based on the collected electrical energy, the target electrical energy, and the number of remaining days, generate schedule information such that the electronic apparatus 100 operates in the power-saving mode for the remaining period, and determine an operation mode of the electronic apparatus 100 based on the schedule information.

The electrical energy prediction command may be a preset event to calculate predicted electrical energy over a preset period of time.

When the preset event occurs, the one or more processors 120 may execute an electrical energy automatic management mode to automatically control electrical energy.

The electrical energy automatic management mode may mean a mode in which the power-saving mode is performed for a portion of the preset period based on the target electrical energy. The electrical energy automatic management mode may be described as an AI power-saving mode. The electrical energy automatic management mode may mean a mode in which the electronic apparatus 100 operates based on the schedule information. The schedule information may include information for determining an operation mode of the electronic apparatus 100 over time.

The preset event may include one of an event where an electrical energy prediction command is received by the user, an event where a preset unit of time set by the user has elapsed, or an event where it is before a threshold time from the end of a preset period.

The event where an electrical energy prediction command is received by the user may be an event where a user input for managing electrical energy is received. Specifically, the event where an electrical energy prediction command is received by the user may be an event in which a user input for executing an application for managing electrical energy is received.

The event where a preset unit of time set by the user has elapsed may be an event where a time condition set by the user occurs. The preset unit of time may be 24 hours, one week, or one month. Also, the preset unit of time may be arbitrarily set by the user, such as 72 hours.

The event where it is before a threshold time from the end of a preset period may mean an event where a specific point in time arrives before the end of the preset period. For example, when the preset period is one month and the threshold time is one week, the one or more processors 120 may identify that the preset event occurs on the 22nd, which is one week before the end of the one-month period.

According to various embodiments, the preset event may mean an event where a threshold percentage of the total number of days in the preset period has elapsed. For example, when the preset period is 30 days and the threshold percentage is 70%, the one or more processors 120 may identify that the preset event occurs on the 22nd when 70% of the total number of days in the preset period has elapsed.

In addition, in order to operate in the electrical energy automatic management mode, the one or more processors 120 may perform the operations of acquiring collected electrical energy, acquiring predicted electrical energy, and acquiring the number of remaining days. Further, the one or more processors 120 may generate schedule information by calculating a first number of operating days in a normal mode and a second number of operating days in a power-saving mode for a period of time corresponding to the number of remaining days.

According to various embodiments, the one or more processors 120 may collect (or measure) electrical energy in real time. The one or more processors 120 may acquire the collected electrical energy in real time. The one or more processors 120 may acquire the collected electrical energy (or cumulative electrical energy) from the start of the preset period to the present time. The one or more processors 120 may determine whether the collected electrical energy exceeds a threshold percentage of the target electrical energy. For example, the threshold percentage may be 80%. When the electrical energy reaches the threshold percentage (80%) of the target electrical energy, the one or more processors 120 may determine that there is a need to control the electronic apparatus 100 into a power-saving mode.

When the preset event occurs, the one or more processors 120 may acquire the collected electrical energy. The collected electrical energy may be acquired in various ways.

According to various embodiments, the one or more processors 120 may measure electrical energy using a sensor. The sensor may refer to various devices that measure electrical energy. The sensor may be a power sensor, a smart meter, an energy meter, or the like.

The electronic apparatus 100 may further include a sensor for measuring electrical energy, and the one or more processors 120 may collect the electrical energy for a preset period. When an electrical energy prediction command is received, the one or more processors 120 may acquire the collected electrical energy from the time when the preset period starts to the time when the electrical energy prediction command is received.

According to various embodiments, the one or more processors 120 may acquire electrical energy through an external server. The external server may be a server that measures electrical energy for billing purposes. The external server may collect the total amount of electrical energy consumed in the home. Subsequently, when a request for electrical energy is received from the electronic apparatus 100, the external server may transmit the electrical energy corresponding to the request to the electronic apparatus 100. The one or more processors 120 may receive the electrical energy from the external server.

Meanwhile, the electronic apparatus 100 may further include a communication interface connected to an external server, and when the collected electrical energy is not received, the one or more processors 120 may request from the external server via the communication interface the collected electrical energy from the time when the preset period starts to the time when the electrical energy prediction command is received in an electrical energy collection server, and receive the collected electrical energy from the external server via the communication interface.

Meanwhile, the one or more processors 120 may acquire the collected electrical energy from the time when the preset period starts to the time when the electrical energy prediction command is received. The collected electrical energy may refer to electrical energy consumed by the electronic apparatus 100 over a specific period of time. The collected electrical energy may be the accumulated electrical energy from the start of the preset period to the present time. Accordingly, the collected electrical energy may be described as cumulative electrical energy.

For example, when the preset period is June 1 to June 30, and the time when the electrical energy prediction command is received is June 10, the one or more processors 120 may acquire the electrical energy accumulated from June 1 to June 10 as the collected electrical energy.

Once the collected electrical energy is acquired, the one or more processors 120 may acquire predicted electrical energy. The predicted electrical energy may refer to the predicted electrical energy that is expected to be consumed in the preset period.

For example, when the preset period is June 1 to June 30, and the time when the electrical energy prediction command is received is June 10, the one or more processors 120 may predict the electrical energy that is expected to be consumed from June 1 to June 30.

Meanwhile, the one or more processors 120 may acquire the number of elapsed days from the time when the preset period starts to the time when the electrical energy prediction command is received, and acquire predicted electrical energy corresponding to the preset period based on the collected electrical energy, the number of elapsed days, and the total number of days in the preset period.

The number of elapsed days may indicate how many days have passed since the start of the electrical energy measurement when the electrical energy prediction command was received.

The one or more processors 120 may acquire daily average electrical energy based on the collected electrical energy and the number of elapsed days. In addition, the one or more processors 120 may acquire predicted electrical energy based on the daily average electrical energy and the total number of days in the preset period.

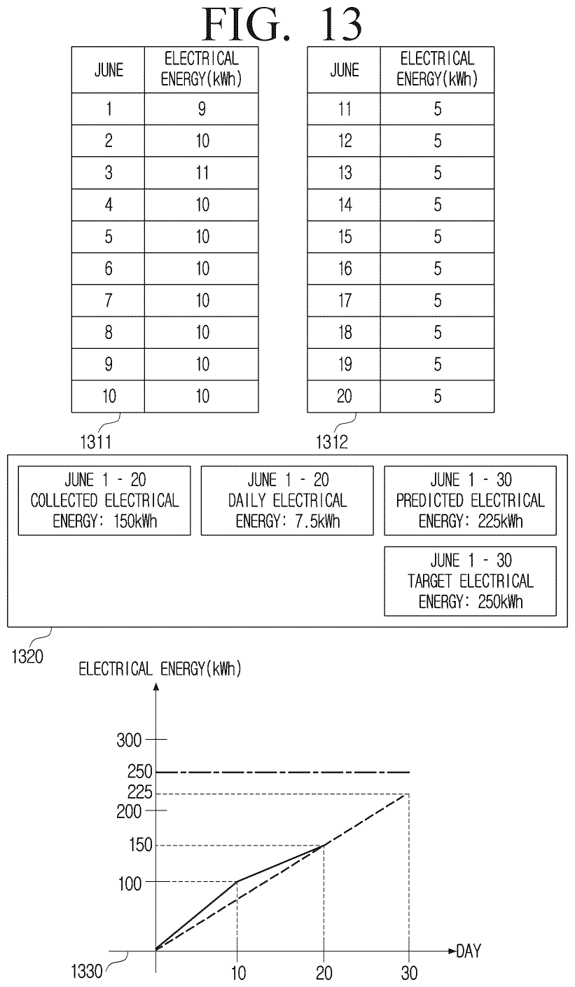

According to various embodiments, the one or more processors 120 may calculate daily average electrical energy by dividing the collected electrical energy by the number of elapsed days. The one or more processors 120 may then multiply the daily average electrical energy by the total number of days in the preset period to acquire predicted electrical energy corresponding to the preset period. An embodiment thereof will be described in FIG. 13.

For example, when the preset period is June 1 to June 30, and 10 days have elapsed since the electrical energy prediction command was received, the one or more processors 120 may determine the number of elapsed days as 10 days. When the collected electrical energy from June 1 to June 10 is 100 kWh, the one or more processors 120 may determine that the daily average electrical energy is 10 kWh. The one or more processors 120 may multiply the daily average electrical energy (10 kWh) by the total number of days in the preset period (30 days) to acquire predicted electrical energy (300 kWh).

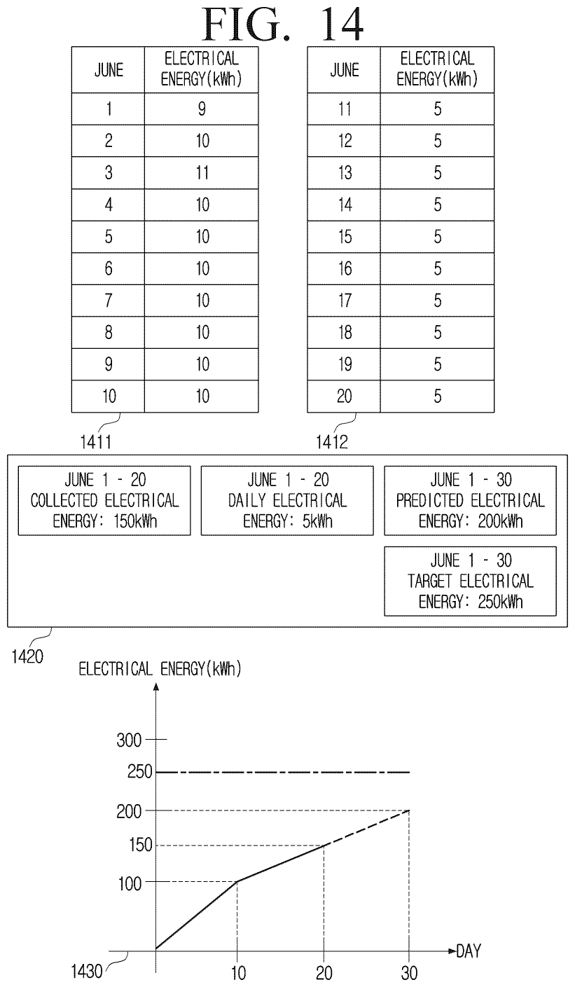

According to various embodiments, the usage pattern of the electrical energy may not be constant based on the present time (when the electrical energy prediction command is received). For example, the power usage may be high in the first period and low in the second period. The one or more processors 120 may acquire predicted electrical energy based on the electrical energy consumed in a recent period (the second period). The first and second periods may be distinguished based on power consumption patterns. The one or more processors 120 may acquire the electrical energy on a daily basis, and determine whether the acquired electrical energy falls within a certain range. An embodiment thereof will be described in FIG. 14.

Meanwhile, the one or more processors 120 may identify whether the predicted electrical energy exceeds the target electrical energy.

The target electrical energy may be determined based on user settings. According to various embodiments, the target electrical energy may be acquired by a user input. For example, upon receiving target electrical energy set by a user, the one or more processors 120 may store the received target electrical energy in the memory 110.

According to various embodiments, the target electrical energy may be determined based on threshold electrical energy that is automatically set. The user may not select the target electrical energy directly, and default electrical energy may be set as the target electrical energy. With respect to the electrical energy of the electronic apparatus 100, average electrical energy may be set in advance. Thus, when there is no user input, the target electrical energy may be determined as a preset value. The target electrical energy may be described as default electrical energy or standard electrical energy.

When the predicted electrical energy does not exceed the target electrical energy, the one or more processors 120 may continue to measure electrical energy or wait for a preset event to occur.

When the predicted electrical energy exceeds the target electrical energy, the one or more processors 120 may determine that a power-saving mode is required. The one or more processors 120 may determine how long the power-saving mode will be performed.

When the predicted electrical energy exceeds the target electrical energy, the one or more processors 120 may calculate the number of remaining days of the total number of days in the preset period. The number of remaining days may represent the number of days from the time when the electrical energy prediction command is received to the time when the present period ends. The number of remaining days may be acquired by subtracting the number of elapsed days from the total number of days in the preset period.

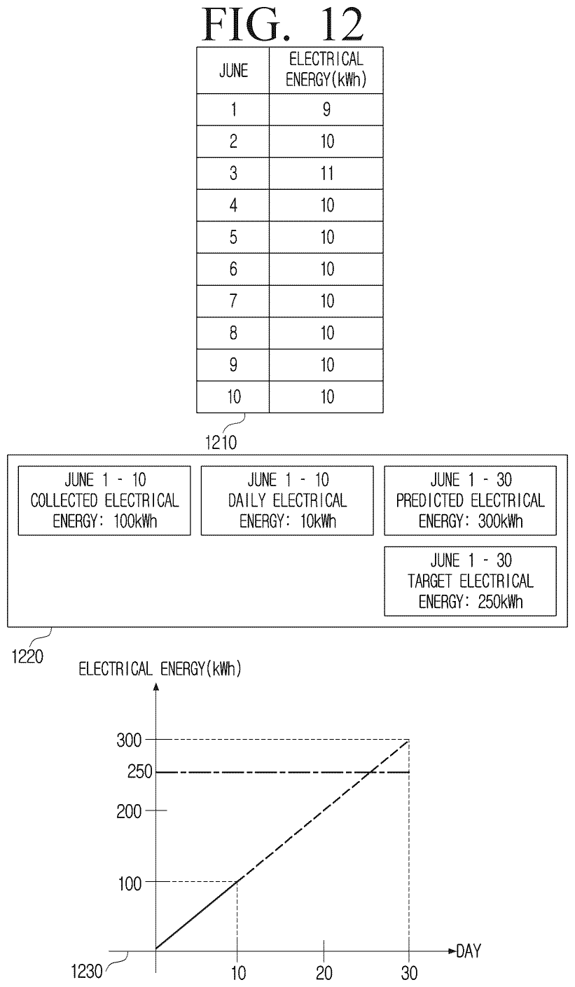

Various embodiments related to collected electrical energy, the predicted electrical energy, and the target electrical energy will be described in FIGS. 12 through 16.

Meanwhile, the one or more processors 120 may acquire a first number of operating days in a normal mode and a second number of operating days in a power-saving mode based on the collected electrical energy, the target electrical energy and the number of remaining days.

Specifically, the one or more processors 120 may acquire remaining electrical energy by subtracting the collected electrical energy from the target electrical energy. The remaining electrical energy may represent the electrical energy that needs to be consumed for the number of remaining days to avoid exceeding the target electrical energy. The one or more processors 120 may calculate the number of operating days that need to be operated in a power-saving mode (second number of operating day) by considering the remaining electrical energy and the number of remaining days.

Meanwhile, the one or more processors 120 may acquire the remaining electrical energy by subtracting the collected electrical energy from the target electrical energy, acquire daily electrical energy for the normal mode and daily electrical energy for the power-saving mode, and acquire the second number of operating days based on the daily electrical energy for the normal mode, the daily electrical energy for the power-saving mode, the remaining electrical energy, and the number of remaining days.

The daily electrical energy for the normal mode may refer to daily electrical energy consumed by the electronic apparatus 100 operating in the normal mode.

The daily electrical energy for the power-saving mode may refer to daily electrical energy consumed by the electronic apparatus 100 operating in the power-saving mode.

The daily electrical energy for the normal mode and the daily electrical energy for the power-saving mode may each be stored in the memory 110 as preset values.

The daily electrical energy for the normal mode may be described as the reference (standard) electrical energy in the normal mode, and the daily electrical energy for the power-saving mode may be described as the reference (standard) electrical energy in the power-saving mode.

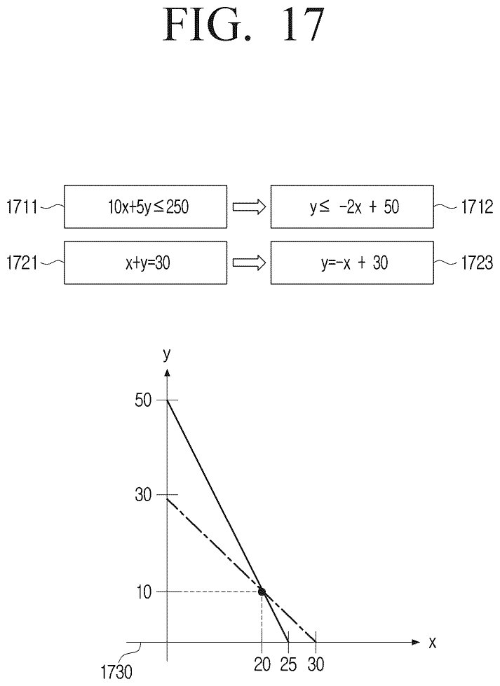

Specific operations of calculating the first number of operating days and the second number of operating days will be described in FIGS. 17 through 19.

Meanwhile, the one or more processors 120 may acquire the first number of operating days by subtracting the second number of operating days from the remaining period.

The remaining period may be a sum of the first number of operating days operating in the normal mode and the second number of operating days operating in the power-saving mode. The one or more processors 120 may acquire the first number of operating days operating in the normal mode and the second number of operating days operating in the power-saving mode in the remaining period.

The one or more processors 120 may generate schedule information by considering the first number of operating days and the second number of operating days. The one or more processors 120 may operate the electronic apparatus 100 for the number of remaining days based on the generated schedule information.

The one or more processors 120 may determine when to start the power-saving mode. The start time of the power-saving mode may be determined in various ways.

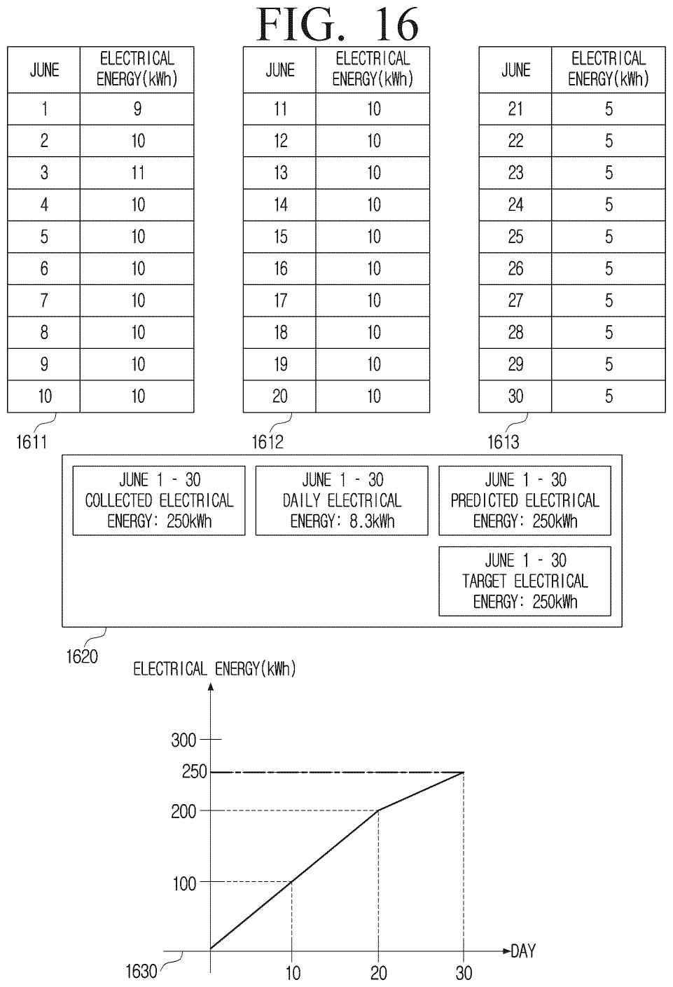

According to various embodiments, the normal mode may be performed first, followed by the power-saving mode. The one or more processors 120 may generate schedule information such that the electronic apparatus 100 operates in the normal mode for the first number of operating days of the remaining period and then, operates in the power-saving mode for the second number of operating days. An embodiment thereof will be described in FIG. 16.

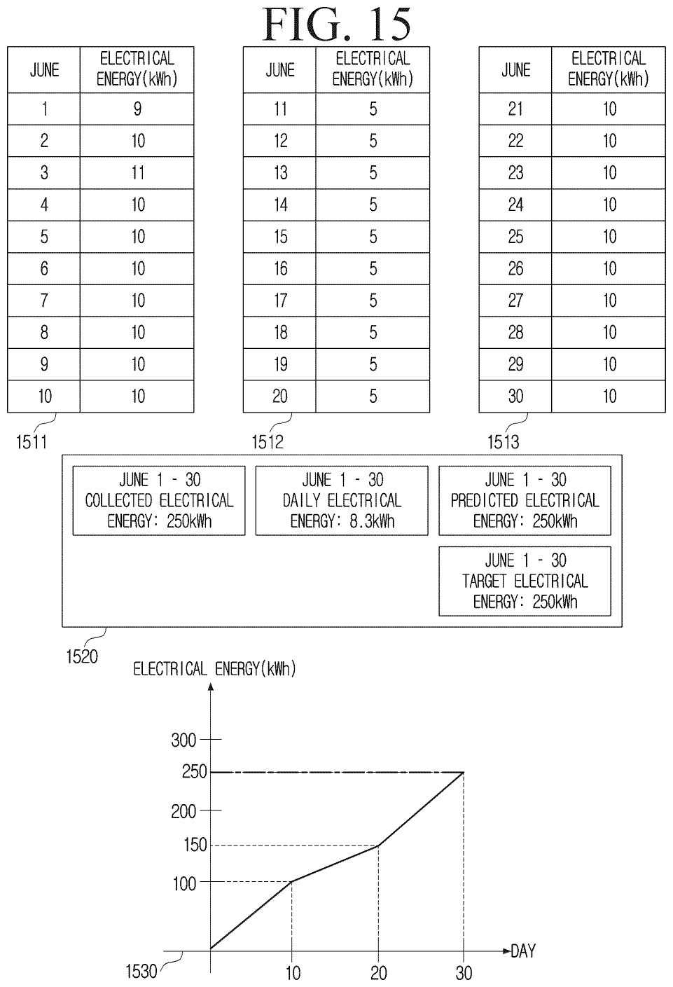

According to various embodiments, the power-saving mode may be performed first, followed by the normal mode. The one or more processors 120 may generate schedule information such that the electronic apparatus 100 operates in the power-saving mode for the second number of operating days of the remaining period and then, operates in the normal mode for the first number of operating days. An embodiment thereof will be described in FIG. 15.

According to various embodiments, the normal mode and the power-saving mode may be performed alternately. The one or more processors 120 may generate scheduling information such that the normal mode and the power-saving mode are performed alternately. For example, the one or more processors 120 may operate in the normal mode on June 11, operate in the power-saving mode on June 12, and operate in the normal mode on June 13.

Meanwhile, the electronic apparatus 100 may further include a display and control the display to display a screen including information about the target electrical energy, and the screen may include at least one of a user interface (UI) for receiving a user input related to automatic control of the power-saving mode or a UI for receiving a user input related to the target electrical energy.

The screen including information about the target electrical energy may be a screen provided by the application for managing electrical energy.

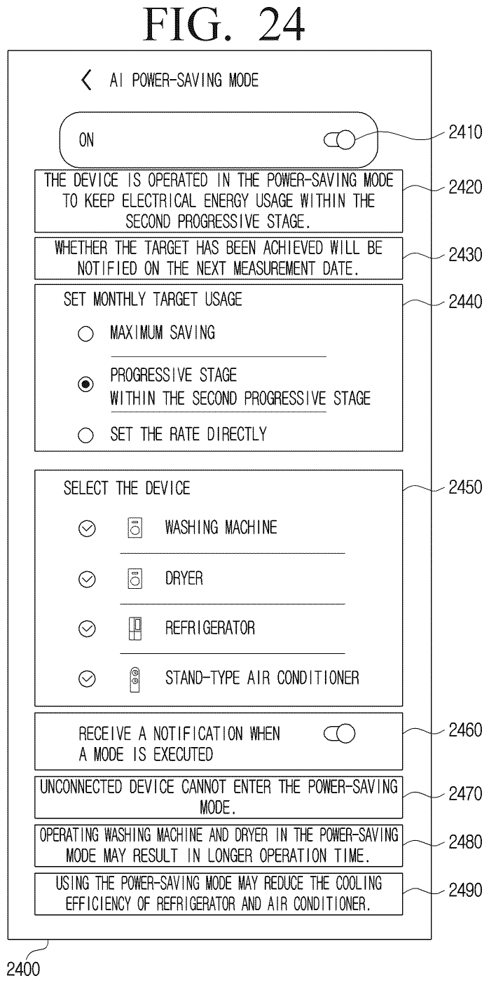

The UI for receiving a user input related to automatic control of the power-saving mode may refer to a UI 2410 of FIG. 24. Upon receiving the user input via the UI 2410, the one or more processors 120 may determine whether to perform the automatic electrical energy management mode based on the user input.

The UI for receiving a user input related to the target electrical energy may refer to a UI 2440 of FIG. 24. Upon receiving the user input via the UI 2440, the one or more processors 120 may determine target electrical energy based on the user input.

Meanwhile, the UI for receiving a user input related to the target electrical energy may be a UI for selecting one of a plurality of preset progressive tax sections.

Meanwhile, the collected electrical energy may be first collected electrical energy, the predicted electrical energy may be first predicted electrical energy, the number of remaining days may be the first number of remaining days, the schedule information may be first schedule information, and when a second electrical energy prediction command is received, the one or more processors 120 may acquire second collected electrical energy from the time when the preset period starts to the time when the second electrical energy prediction command is received, acquire second predicted electrical energy corresponding to the preset period based on the second collected electrical energy, when the second predicted electrical energy exceeds the target electrical energy, acquire the second number of remaining days from the time when the second electrical energy prediction command is received to the time when the preset period ends, change the first schedule information to the second schedule information by changing the second number of operating days based on the second collected electrical energy, the target electrical energy, and the second number of remaining days, and determine an operation mode of the electronic apparatus 100 based on the changed second schedule information.

The one or more processors 120 may change (or update) the schedule information based on a preset event. There may be an error in the operation of generating schedule information by calculating the first number of operating days and the second number of operating days.

The reason for the error is that the predicted electrical energy, the daily electrical energy for the normal mode, and the daily electrical energy for the power-saving mode are calculated by prediction.

Thus, the one or more processors 120 may identify whether a second event (second electrical energy prediction command) occurs after the first event (first electrical energy prediction command) occurs. When it is identified that the second event occurs, the one or more processors 120 may determine whether to change the existing schedule information.

The one or more processors 120 may newly acquire collected electrical energy, predicted electrical energy, and the number of remaining days based on the new time when (the time when the second electrical energy prediction command is received). Since only the point in time has changed and the calculation operations is the same as before, redundant description will be omitted.

For example, it is assumed that the preset period is June 1 to June 30, the electrical energy prediction command is received on June 10, and the electronic apparatus 100 operated until June 20 based on the first schedule information generated on June 10. When a new electrical energy prediction command is received on June 20, the electronic apparatus 100 may generate the second schedule information based on June 20. The electronic apparatus 100 may operate based on the second schedule information generated on June 20.

According to various embodiments, the electronic apparatus 100 may automatically operate in the power-saving mode in order to consume electrical energy within target electrical energy. Thus, the user does not need to directly change the operation mode of the electronic apparatus 100.

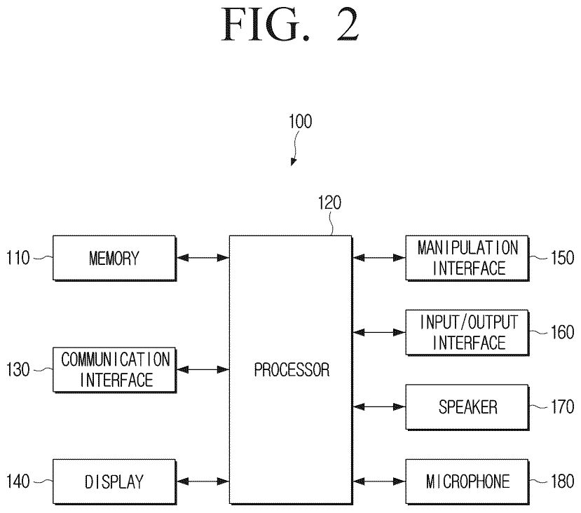

Meanwhile, only brief configuration of the electronic apparatus 100 has been shown and described above, but various additional configurations may be provided during implementation. An embodiment thereof will be described in FIG. 2.

FIG. 2 is a block diagram illustrating specific configuration of the electronic apparatus 100 in FIG. 1 according to an embodiment of the disclosure.

Referring to FIG. 2, the electronic apparatus 100 may include at least one of the memory 110, the one or more processors 120, a communication interface 130, a display 140, a manipulation interface 150, an input/output interface 160, a speaker 170, or a microphone 180. Meanwhile, redundant descriptions of the same operations as described above will be omitted.

The memory 110 may be implemented as an internal memory such as read-only memory (ROM) (e.g., electrically erasable programmable read-only memory (EEPROM)) and random access memory (RAM) included in the one or more processors 120, or may be implemented as a separate memory. In this case, the memory 110 may be implemented as memory embedded in the electronic apparatus 100 or as memory detachable from the electronic apparatus 100 depending on the data storage purpose. For example, in the case of data for driving the electronic apparatus 100, the data may be stored in the memory embedded in the electronic apparatus 100, and in the case of data for the expansion function of the electronic apparatus 100, the data may be stored in memory detachable from the electronic apparatus 100.

Meanwhile, the memory embedded in the electronic apparatus 100 may be implemented as at least one of a volatile memory (e.g. a dynamic RAM (DRAM), a static RAM (SRAM), or a synchronous dynamic RAM (SDRAM)) or a non-volatile memory (e.g., a one-time programmable ROM (OTPROM), a programmable ROM (PROM), an erasable and programmable ROM (EPROM), an electrically erasable and programmable ROM (EEPROM), a mask ROM, a flash ROM, a flash memory (e.g. a NAND flash or a NOR flash), a hard drive, or a solid state drive (SSD)), and the memory detachable from the electronic apparatus 100 may be implemented in the form of memory card (e.g., a compact flash (CF), a secure digital (SD), a micro secure digital (Micro-SD), a mini secure digital (Mini-SD), an extreme digital (xD), or a multi-media card (MMC)), an external memory connectable to a USB port (e.g., a USB memory), or the like.

The one or more processors 120 may perform the overall control operation of the electronic apparatus 100. Specifically, the one or more processors 120 performs the function of controlling the overall operation of the electronic apparatus 100.

The one or more processors 120 may be implemented as a digital signal processor (DSP) for processing digital signals, a microprocessor, or a time controller (TCON). However, the one or more processors 120 is not limited thereto, and the one or more processors 120 may include one or more of a central processing unit (CPU), a micro controller unit (MCU), a micro processing unit (MPU), a controller, an application processor (AP), a graphics-processing unit (GPU), a communication processor (CP), and an advanced reduced instruction set computer (RISC) machines (ARM) processor, or may be defined as the corresponding term. In addition, the one or more processors 120 may be implemented as a system on chip (SoC) with embedded processing algorithms, a large-scale integration (LSI), or in the form of a field programmable gate array (FPGA). Further, the one or more processors 120 may perform various functions by executing computer executable instructions stored in the memory.

The communication interface 130 is configured to perform communication with various types of external devices according to various types of communication methods. The communication interface 130 may include wireless or wired communication modules. Here, each communication module may be implemented as at least one hardware chip.

The wireless communication module may be a module that performs communication with an external device wirelessly. For example, the wireless communication module may include at least one of a Wi-Fi module, a Bluetooth module, an infrared communication module or other communication modules.

The Wi-Fi module and the Bluetooth module may perform communication using a Wi-Fi method and a Bluetooth method, respectively. When using a Wi-Fi module or a Bluetooth module, various connection information such as service set identifier (SSID) and session keys are first transmitted and received, and various information can be transmitted and received after establishing a communication connection using the same.

The infrared communication module performs communication according to an infrared data association (IrDA) communication technology which transmits data wirelessly over a short distance using infrared rays between optical light and millimeter waves.

In addition to the above-described communication methods, at least one communication chip that performs communication according to various wireless communication standards, such as Zigbee, 3rd Generation (3G), 3rd Generation Partnership Project (3GPP), Long Term Evolution (LTE), LTE Advanced (LTE-A), 4th Generation (4G), 5th Generation (5G), etc. may be included.

The wired communication module may be a module that performs communication with an external device via cable. For example, the wired communication module may include at least one of a local area network (LAN) module, an Ethernet module, pair cables, coaxial cables, fiber optic cables, or an Ultra Wide-Band (UWB) module.

The display 140 may be implemented as various types of displays, such as liquid crystal displays (LCDs), organic light emitting diodes (OLEDs) displays, plasma display panels (PDPs), and the like. The display 140 may also include a driving circuit, a backlight unit, and the like, which may be implemented in the form of a-si thin film transistors (TFTs), low temperature poly silicon (LTPS) TFTs, organic TFTs (OTFTs), and the like. Meanwhile, the display 140 may be implemented as a touch screen combined with a touch sensor, a flexible display, a three-dimensional (3D) display, and the like. In addition, the display 140 according to an embodiment may include not only a display panel that outputs images but also a bezel that houses a display panel. In particular, the bezel according to an embodiment may include a touch sensor (not shown) for sensing a user interaction.

The manipulation interface 150 may be implemented as a button, a touch pad, a mouse, a keyboard, etc., or may be implemented as a touch screen that can also perform a display function and a manipulation input function. Here, the button may be a various types of buttons such as a mechanical button, a touch pad, a wheel, etc. formed in any arbitrary area such as front, side, back, etc.

The input/output interface 160 may any one of High Definition Multimedia Interface (HDMI), Mobile High-Definition Link (MHL), Universal Serial Bus (USB), Display Port (DP), Thunderbolt, Video Graphics Array (VGA) port, RGB port, D-subminiature (D-SUB), or Digital Visual Interface (DVI). The input/output interface 160 may be implemented as an interface that inputs/outputs at least one of audio signals or video signals. Depending on implementation, the input/output interface 160 may be implemented as a port that inputs/outputs only audio signals and a port that inputs/outputs only video signals as separate ports, or may be implemented as a single port that inputs/outputs both audio signals and video signals. Meanwhile, the electronic apparatus 100 may transmit at least one of audio signals or video signals to an external device (e.g., an external display device or an external speaker) through the input/output interface 160. Specifically, an output port included in the input/output interface 160 may be connected to an external device, and the electronic apparatus 100 may transmit at least one of audio signals or video signals to the external device through the output port.

Here, the input/output interface 160 may be connected to a communication interface. The input/output interface 160 may transmit information received from an external device to the communication interface, or transmit information received through the communication interface to the external device.

The speaker 170 may be configured to output various notification sounds or voice messages as well as various audio data.

The microphone 180 is configured to receive a user voice or other sound and convert it into audio data. The microphone 180 may receive a user voice in an activated state. For example, the microphone 180 may be integrally formed in the direction of the top, front, side, etc. of the electronic apparatus 100. The microphone 180 may include various components such as a microphone that collects a user voice in an analog form, an amplification circuit that amplifies the collected user voice, an A/D conversion circuit that samples the amplified user voice and converts it into a digital signal, a filter circuit that removes noise components from the converted digital signal, etc.

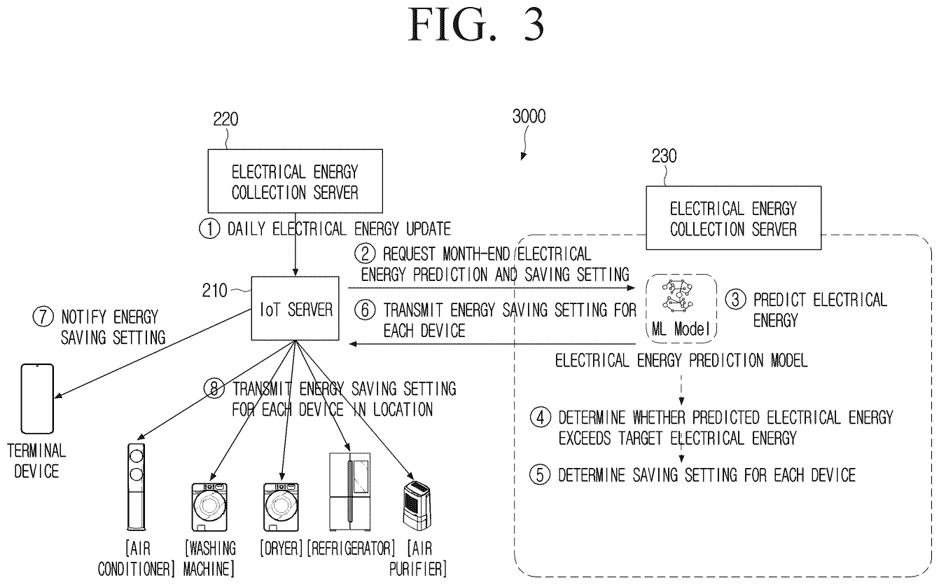

FIG. 3 is a view provided to explain an electrical energy management system 3000 according to an embodiment of the disclosure.

Referring to FIG. 3, the system 3000 may include at least one of an Internet of thing (IoT) server 210, an electrical energy collection server 220, or an electrical energy management server 230.

The IoT server 210 may be a host device or a hub device that is connected to a plurality of devices or terminal devices. The plurality of devices may represent home appliances (e.g., air conditioners, washers, dryers, refrigerators, air purifiers). The terminal devices may refer to smartphones or tablets carried by a user.

The IoT server 210 may transmit a request for electrical energy to the electrical energy collection server 220 in order to acquire the electrical energy consumed by the plurality of devices connected to the IoT server 210.

The electrical energy collection server 220 may acquire the collected electrical energy corresponding to the IoT server 210 in response to the request received from the IoT server 210. Subsequently, the electrical energy collection server 220 may transmit the collected electrical energy to the IoT server 210. The electrical energy collection server 220 may transmit the collected electrical energy to the IoT server 210 once per day.

The IoT server 210 may store (or update) the electrical energy based on the collected electrical energy received from the electrical energy collection server 220. The IoT server 210 may request the electrical energy management server 230 to set predicted electrical energy and savings for a preset period (e.g., monthly) based on the collected electrical energy received from the electrical energy collection server 220.

The electrical energy management server 230 may predict the predicted electrical energy in response to the request received from the IoT server 210. The electrical energy management server 230 may acquire the predicted electrical energy for the preset period (e.g., monthly) based on the electrical energy collected through an electrical energy prediction model. The electrical energy management server 230 may then compare the predicted electrical energy with the target electrical energy. The electrical energy management server 230 may determine whether the predicted electrical energy exceeds the target electrical energy. When the predicted electrical energy exceeds the target electrical energy, the electrical energy management server 230 may determine saving setting for each of the plurality of devices. The electrical energy management server 230 may transmit the determined saving setting for each of the plurality of devices to the IoT server 210.

The IoT server 210 may receive the saving setting determined for each of the plurality of devices from the electrical energy management server 230. The IoT server 210 may then transmit a notification related to the saving setting to a terminal device. The terminal device may display the notification related to the saving setting received from the IoT server 210. Further, the IoT server 210 may transmit the saving setting determined for each of the plurality of devices to each of the plurality of devices. The plurality of devices may perform the power-saving mode based on the saving setting received from the IoT server 210.

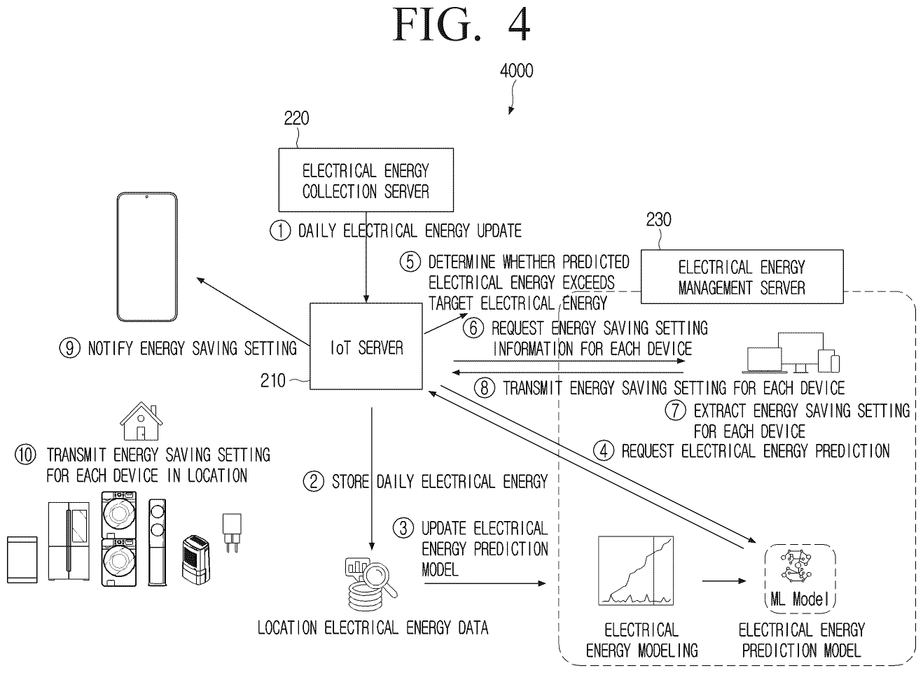

FIG. 4 is a view provided to explain an electrical energy management system 4000 according to an embodiment of the disclosure.

Referring to FIG. 4, the system 4000 may include at least one of the IoT server 210, the electrical energy collection server 220, or the electrical energy management server 230.

The IoT server 210 may request the electrical energy in a particular home from the electrical energy collection server 220. The electrical energy collection server 220 may transmit the electrical energy in the particular home to the IoT server 210. The IoT server 210 may store the electrical energy received from the electrical energy collection server 220 on a daily basis. The IoT server 210 may then transmit the daily electrical energy to the electrical energy management server 230.

The electrical energy management server 230 may update the electrical energy prediction model based on the daily electrical energy received from the IoT server 210. The electrical energy management server 230 may update the electrical energy prediction model based on the collected electrical energy received on a daily basis.

The IoT server 210 may request predicted electrical energy from the electrical energy management server 230 based on a preset event. Upon receiving the request related to the electrical energy prediction from the IoT server 210, the electrical energy management server 230 may acquire the predicted electrical energy for the preset period through the updated electrical energy prediction model. The electrical energy management server 230 may then transmit the predicted electrical energy to the IoT server 210.

The IoT server 210 may receive the predicted electrical energy from the electrical energy management server 230.

Subsequently, the IoT server 210 may compare the predicted electrical energy with the target electrical energy. The IoT server 210 may determine whether the predicted electrical energy exceeds the target electrical energy. When the predicted electrical energy exceeds the target electrical energy, the IoT server 210 may request saving setting for each of the plurality of device from the electrical energy management server 230.

Upon receiving the request for saving setting from the IoT server 210, the electrical energy management server 230 may determine the saving setting for each of the plurality of devices. The electrical energy management server 230 may transmit the determined saving setting for each of the plurality of devices to the IoT server 210.

The IoT server 210 may receive the saving setting determined for each of the plurality of devices from the electrical energy management server 230. The IoT server 210 may then transmit a notification related to the saving setting to a terminal device. The terminal device may display the notification related to the saving setting received from the IoT server 210. Further, the IoT server 210 may transmit the saving setting determined for each of the plurality of devices to each of the plurality of devices. The plurality of devices may perform the power-saving mode based on the saving setting received from the IoT server 210.

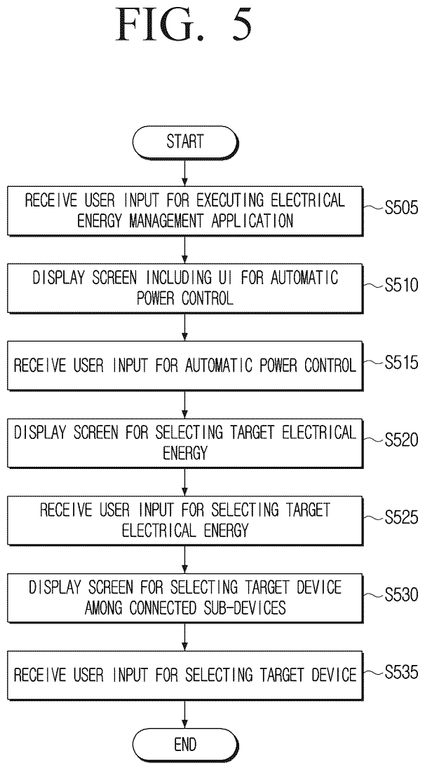

FIG. 5 is a flowchart provided to explain an operation of receiving a user input through an electrical energy management application according to an embodiment of the disclosure.

Referring to FIG. 5, the electronic apparatus 100 may receive a user input for executing the electrical energy management application at operation S505. After the application is executed, the electronic apparatus 100 may display a screen including a UI for automatic power control at operation S510. The UI for automatic power control may correspond to the UI 2410 of FIG. 24. The electronic apparatus 100 may receive a user input for automatic power control via the UI included on the screen at operation S515.

Further, the electronic apparatus 100 may display a screen for selecting target electrical energy at operation S520. The electronic apparatus 100 may receive a user input for selecting the target electrical energy at operation S525. The screen for selecting the target electrical energy may correspond to the UI 2440 of FIG. 24.

In addition, the electronic apparatus 100 may display a screen for selecting a target device among connected sub-devices at operation S530. The electronic apparatus 100 may receive a user input for selecting the target device at operation S535.

The electronic apparatus 100 may acquire the target electrical energy and the target device based on the received user input(s). The electronic apparatus 100 may control the target device to perform the power-saving mode in order to consume only the target electrical energy for the preset period.

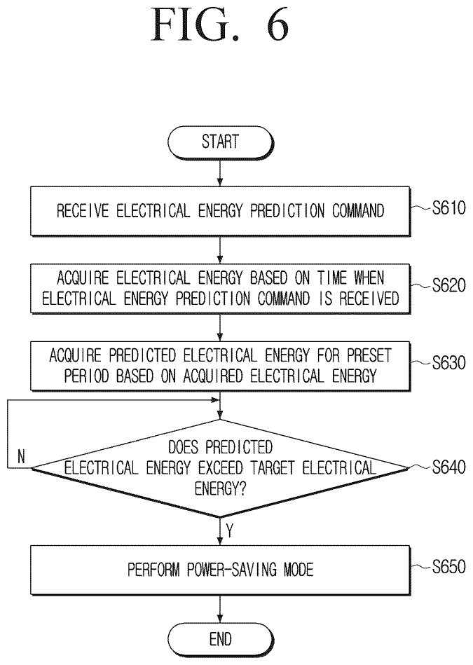

FIG. 6 is a flowchart provided to explain an operation of performing a power-saving mode by comparing target electrical energy with predicted electrical energy according to an embodiment of the disclosure.

Referring to FIG. 6, the electronic apparatus 100 may receive an electrical energy prediction command at operation S610. The electronic apparatus 100 may acquire electrical energy based on the time (present time) when the electrical energy prediction command is received at operation S620. The electronic apparatus 100 may acquire predicted electrical energy for the preset period based on the acquired electrical energy at operation S630. The electronic apparatus 100 may identify whether the predicted electrical energy exceeds the target electrical energy at operation S640.

When the predicted electrical energy does not exceed the target electrical energy at operation S640—N, the electronic apparatus 100 may repeat operations S610 through S640.

When the predicted electrical energy exceeds the target electrical energy at operation S640—Y, the electronic apparatus 100 may perform the power-saving mode at operation S650.

According to various embodiments, the power-saving mode may be performed by the electronic apparatus 100.

According to various embodiments, the power-saving mode may be performed by a plurality of devices (or target devices) connected to the electronic apparatus 100.

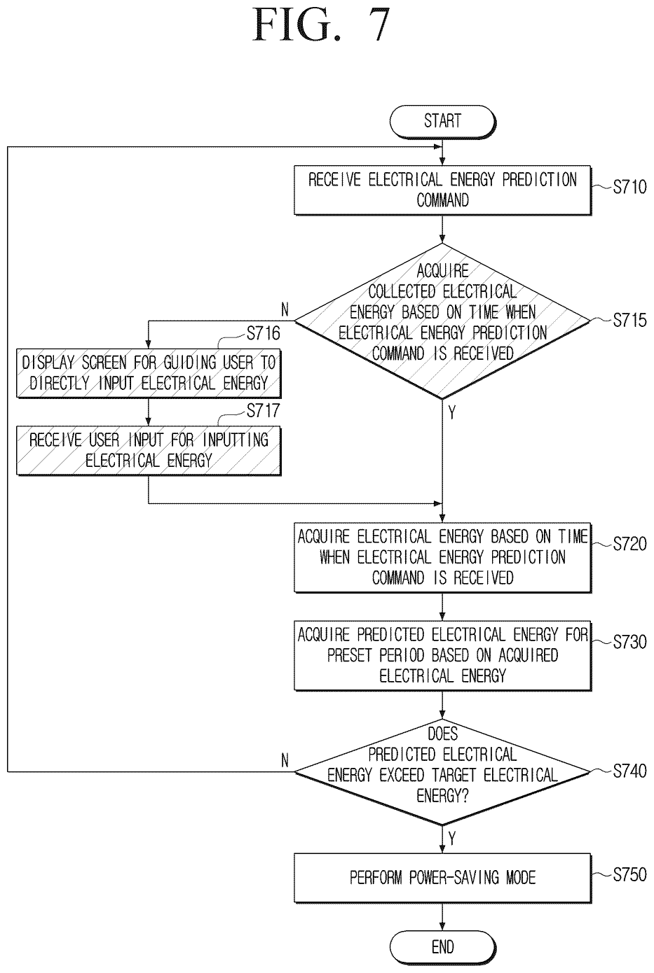

FIG. 7 is a flowchart provided to explain an operation of receiving electrical energy directly from a user according to an embodiment of the disclosure.

Operations S710, S720, S730, S740, and S750 of FIG. 7 may correspond to operations S610, S620, S630, S640, and S650 of FIG. 6. Accordingly, redundant descriptions will be omitted.

After the electrical energy prediction command is received, the electronic apparatus 100 may determine whether the collected electrical energy is acquired based on the time when the electrical energy prediction command is received (the present time) at operation S715. The collected electrical energy may refer to the electrical energy consumed at the present time. The collected electrical energy may mean the electrical energy consumed cumulatively from the start of the preset period to the present time.

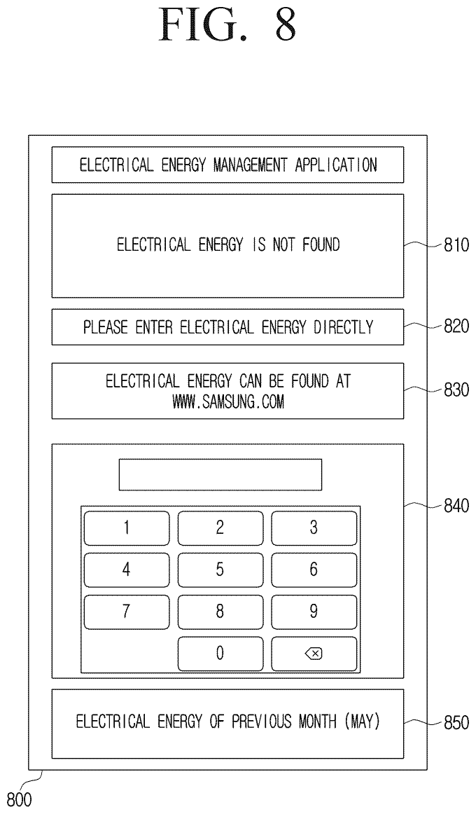

When the collected electrical energy is not acquired at operation S715—N, the electronic apparatus 100 may display a screen for guiding the user to directly input the electrical energy at operation S716. Subsequently, the electronic apparatus 100 may receive a user input for inputting the electrical energy via the displayed screen at operation S717. The displayed screen will be described in FIG. 8.

Once the collected electrical energy is acquired at operation S715—Y, the electronic apparatus 100 may perform operations S720 through S750.

FIG. 8 is a view provided to explain an operation of receiving electrical energy directly from a user according to an embodiment of the disclosure.

Referring to FIG. 8, the electronic apparatus 100 may display a screen 800 for guiding the user to directly input the electrical energy. The screen 800 may include at least one of a UI 810 indicating that the electrical energy is not retrieved (or acquired), a text 820 requesting the user to directly input the electrical energy, a UI 830 informing the user of a site where the electrical energy can be checked, a UI 840 for inputting the electrical energy, or a UI 850 indicating the electrical energy consumed in the previous period.

When a user input is received at a location corresponding to the UI 830, the electronic apparatus 100 may display a screen related to the site where the electrical energy can be checked.

Once the electrical energy is input via the UI 840, the electronic apparatus 100 may acquire the collected electrical energy.

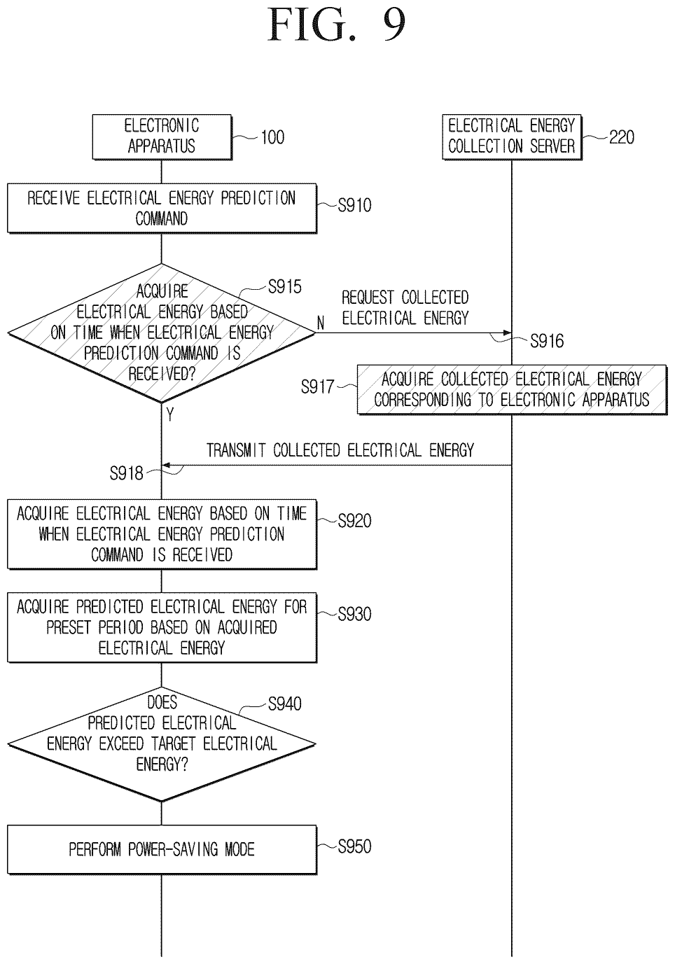

FIG. 9 is a flowchart provided to explain an operation of receiving electrical energy from an external server according to an embodiment of the disclosure.

Operations S910, S920, S930, S940, and S950 of FIG. 9 may correspond to operations S610, S620, S630, S640, and S650 of FIG. 6. Accordingly, redundant descriptions will be omitted.

After the electrical energy prediction command is received, the electronic apparatus 100 may determine whether the collected electrical energy is acquired based on the time when the electrical energy prediction command is received (the present time) at operation S915.

When the collected electrical energy is not acquired at operation S915—N, the electronic apparatus 100 may request the collected electrical energy from the electrical energy collection server 220 at operation S916.

The electrical energy collection server 220 may receive a signal from the electronic apparatus 100 requesting the collected electrical energy. The electrical energy collection server 220 may acquire the collected electrical energy corresponding to the electronic apparatus 100 at operation S917. Then, the electrical energy collection server 220 may transmit the collected electrical energy to the electronic apparatus 100 at operation S918.

The electronic apparatus 100 may acquire the collected electrical energy from the electrical energy collection server 220. Then, the electronic apparatus 100 may perform operations S920 through S950.

Once the collected electrical energy is acquired at operation S915—Y, the electronic apparatus 100 may perform operations S720 through S750.

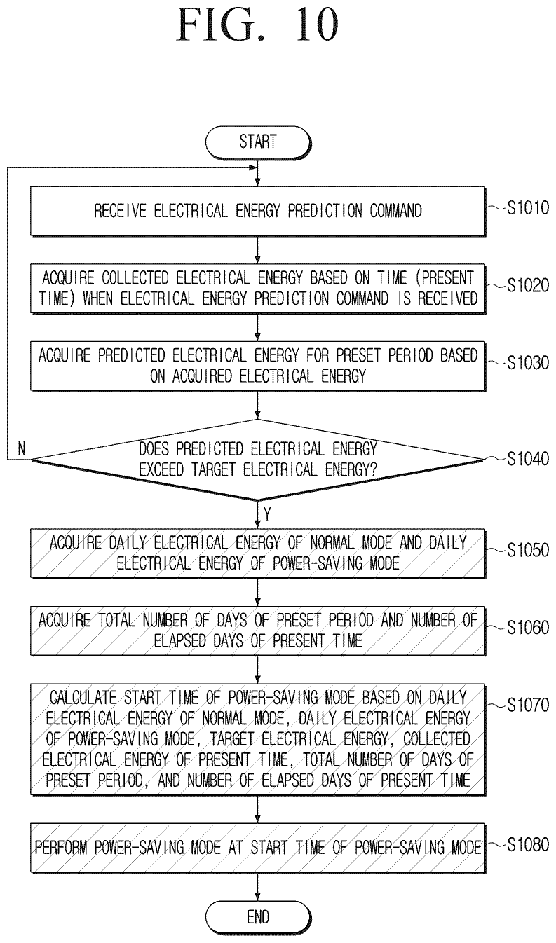

FIG. 10 is a flowchart provided to explain an operation of calculating a start time of a power-saving mode according to an embodiment of the disclosure.

Operations S1010, S1020, S1030, and S1040 of FIG. 10 may correspond to operations S610, S620, S630, and S640 of FIG. 6. Therefore, redundant descriptions will be omitted.

When the predicted electrical energy exceeds the target electrical energy at operation S1040—Y, the electronic apparatus 100 may acquire the daily electrical energy of the normal mode and the daily electrical energy of the power-saving mode at operation S1050. Further, the electronic apparatus 100 may acquire the total number of days in the preset period and the number of elapsed days at the current time point (when the electrical energy prediction command is received) at operation S1060. The number of elapsed days may mean the number of days from a point in time in the preset period to the current point in time.

For example, it is assumed that the preset period is June. When the present time is the 10th, the number of elapsed days could be 10.

The electronic apparatus 100 may calculate a start time of the power-saving mode based on the daily electrical energy in the normal mode, the daily electrical energy in the power-saving mode, the target electrical energy, the collected electrical energy at the present time, the number of days in the preset period, and the number of elapsed days at the present time at operation S1070.

Further, the electronic apparatus 100 may perform the power-saving mode at the calculated start time of the power-saving mode at operation S1080.

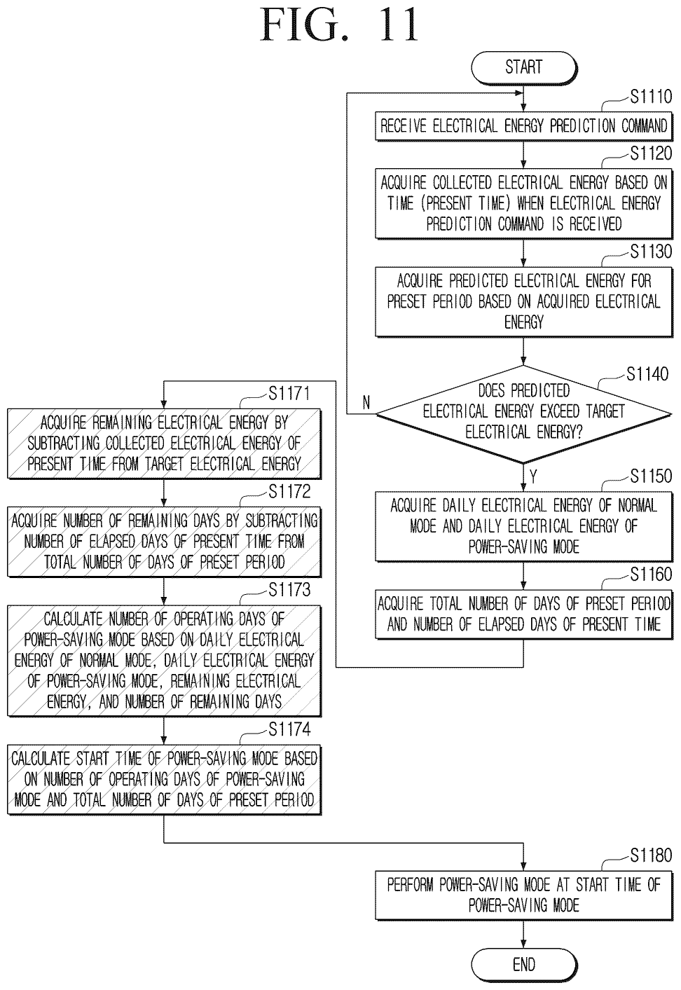

FIG. 11 is a flowchart provided to explain an operation of calculating a start time of a power-saving mode according to an embodiment of the disclosure.

Operations S1110, S1120, S1130, S1140, S1150, S1160, and S1180 of FIG. 11 may correspond to operations S1010, S1020, S1030, S1040, S1050, S1060, and S1080 of FIG. 10. Therefore, redundant descriptions will be omitted.

After acquiring the daily electrical energy in the normal mode, the daily electrical energy in the power-saving mode, the total number of days in the preset period, and the number of elapsed days at the present time (when the electrical energy prediction command is received), the electronic apparatus 100 may acquire remaining electrical energy by subtracting the collected electrical energy at the present time from the target electrical energy at operation S1171.

The electronic apparatus 100 may acquire the number of remaining days by subtracting the number of elapsed days at the present time from the total number of days in the preset period at operation S1172.

The electronic apparatus 100 may calculate the number of operating days in the power-saving mode based on the daily electrical energy in the normal mode, the daily electrical energy in the power-saving mode, the remaining electrical energy, and the number of remaining days at operation S1173.

The electronic apparatus 100 may calculate a start time of the power-saving mode based on the number of operating days in the power-saving mode and the total number of days in the preset period at operation S1174.

A specific calculation method related to the number of operating days in the power-saving mode will be described in FIGS. 17 through 19.

FIG. 12 is a view provided to explain an operation of calculating predicted electrical energy based on electrical energy collected at a present time according to an embodiment of the disclosure.

Referring to FIG. 12, it is assumed that an electrical energy prediction command is received at a certain point in time. It is assumed that the preset period is June 1 to 30, and the electrical energy prediction command is received on June 10.

Table 1210 represents the daily electrical energy consumption from June 1 to June 10.

Data 1220 represents the collected electrical energy (100 kWh) from June 1 to 10, the daily average electrical energy (10 kWh) from June 1 to 10, the predicted electrical energy (300 kWh) from June 1 to 30, and the target electrical energy (250 kWh) for the preset period (June 1 to 30).

The graph 1230 represents the change in electrical energy over a day. The collected electrical energy (or cumulative power) acquired on the 10th may be 100 kWh.

When the electrical energy prediction command is received on the 10th, the electronic apparatus 100 may calculate the predicted electrical energy based on the 10th (the present time). The electronic apparatus 100 may acquire the predicted electrical energy (300 kWh) based on the number of remaining days (20 days) in the preset period, the daily average electrical energy (10 kWh) until the 10th, and the collected electrical energy (100 kWh). The predicted electrical energy may mean predicted electrical energy for the entire preset period (June).

The collected electrical energy (100 kWh) may refer to the cumulative electrical energy from the start time of the preset period (June 1) to the present time (June 10).

The predicted electrical energy (300 kWh) may mean the cumulative electrical energy from the start time of the preset period (June 1) to the end time of the preset period (June 30).

The predicted electrical energy (300 kWh) may be acquired by summing the collected electrical energy (100 kWh) from the start time of the preset period (June 1) to the present time (June 10) and the electrical energy (200 kWh) from the present time (June 10) to the end time of the preset period (June 30).

When the target electrical energy is 250 kWh, the electronic apparatus 100 may determine that the predicted electrical energy (300 kWh) exceeds the target electrical energy (250 kWh).

FIG. 13 is a view provided to explain an operation of calculating predicted electrical energy by considering performance of a power-saving mode according to an embodiment of the disclosure.

Referring to FIG. 13, it is assumed that an electrical energy prediction command is received at a certain point in time. It is assumed that the preset period is from June 1 to June 30, and the electrical energy prediction command is received on June 20.

Table 1311 represents the daily electrical energy consumption from June 1 to June 10.

Table 1312 represents the daily electrical energy consumption from June 11 to June 20.

Data 1320 represents the collected electrical energy (150 kWh) from June 1 to 20, the daily average electrical energy (7.5 kWh) from June 1 to 20, the predicted electrical energy (225 kWh) from June 1 to 30, and the target electrical energy (250 kWh) for the preset period (June 1 to 30).

The graph 1330 represents the change in electrical energy over a day. The collected electrical energy (or cumulative power) acquired on the 20th may be 150 kWh.

When the electrical energy prediction command is received on the 20th, the electronic apparatus 100 may calculate the predicted electrical energy based on the 20th (the present time). The electronic apparatus 100 may acquire the predicted electrical energy (225 kWh) based on the number of remaining days in the preset period (10 days), the daily average electrical energy (7.5 kWh) until the 20th, and the collected electrical energy (150 kWh). The predicted electrical energy may be the predicted electrical energy for the entire preset period (June).

The collected electrical energy (150 kWh) may refer to the cumulative electrical energy from the start time of the preset period (June 1) to the present time (June 20).

The predicted electrical energy (225 kWh) may refer to the cumulative electrical energy from the start time of the preset period (June 1) to the end time of the preset period (June 30).

The predicted electrical energy (225 kWh) may be acquired by summing the collected electrical energy (150 kWh) from the start time of the preset period (June 1) to the present time (June 20) and the electrical energy (75 kWh) from the present time (June 20) to the end time of the preset period (June 30).

When the target electrical energy is 250 kWh, the electronic apparatus 100 may determine that the predicted electrical energy (225 kWh) does not exceed the target electrical energy (250 kWh).

FIG. 14 is a view provided to explain an operation of calculating predicted electrical energy by considering performance of a power-saving mode according to an embodiment of the disclosure.

Referring to FIG. 14, it is assumed that an electrical energy prediction command is received at a certain point in time. It is assumed that the preset period is from June 1 to June 30, and the electrical energy prediction command is received on June 20.

Table 1411 represents the daily electrical energy consumption from June 1 to June 10.

Table 1412 represents the daily electrical energy consumption from June 11 to June 20.

Data 1420 represents the collected electrical energy (150 kWh) from June 1 to 20, the daily average electrical energy (5 kWh) from June 1 to 20, the predicted electrical energy (200 kWh) from June 1 to 30, and the target electrical energy (250 kWh) for the preset period (June 1 to 30).

The graph 1430 represents the change in electrical energy over a day. The collected electrical energy (or cumulative power) acquired on the 20th may be 150 kWh.

When the electrical energy prediction command is received on the 20th, the electronic apparatus 100 may calculate the predicted electrical energy based on the 20th (the present time). The electronic apparatus 100 may acquire the predicted electrical energy (200 kWh) based on the number of remaining days in the preset period (10 days), the average electrical energy (5 kWh) of the past 10 days, and the collected electrical energy (150 kWh). The predicted electrical energy may be the predicted electrical energy for the entire preset period (June).

In FIG. 13, the predicted electrical energy is acquired based on the daily average electrical energy (7.5 kWh) for 20 days (June 1 to June 20). In FIG. 14, the predicted electrical energy is acquired based on the daily average electrical energy (5 kWh) for 10 days (June 10 to June 20).

The collected electrical energy (150 kWh) may refer to the cumulative electrical energy from the start time of the preset period (June 1) to the present time (June 20).

The predicted electrical energy (200 kWh) may refer to the cumulative electrical energy from the start time of the preset period (June 1) to the end time of the preset period (June 30).

The predicted electrical energy (200 kWh) may be acquired by summing the collected electrical energy (150 kWh) from the start time of the preset period (June 1) to the present time (June 20) and the electrical energy (50 kWh) from the present time (June 20) to the end time of the preset period (June 30).

When the target electrical energy is 250 kWh, the electronic apparatus 100 may determine that the predicted electrical energy (200 kWh) does not exceed the target electrical energy (250 kWh).

Meanwhile, as in the embodiment of FIG. 12, when the predicted electrical energy exceeds the target electrical energy, the electronic apparatus 100 may determine to perform the power-saving mode.

The electronic apparatus 100 may perform the power-saving mode for a partial period (10 days) of the number of remaining days (20) to ensure that the electrical energy consumed during the period preset on June 10 does not exceed the target electrical energy. It is assumed that the partial period is 10 days. The electronic apparatus 100 needs to determine when in the number of remaining days (20) to perform the power-saving mode.

FIG. 15 describes an embodiment in which a power-saving mode is performed immediately at the current point in time.

FIG. 16 illustrates an embodiment of performing the power-saving mode at the end of the preset period (June 30). The operation of performing the power-saving mode at the end of the preset period (June 30) may mean that the end time of the power-saving mode is the end time of the preset period (June 30).

FIG. 15 is a view provided to explain an operation of determining a start time of a power-saving mode to be a present time according to an embodiment of the disclosure.

Referring to FIG. 15, it is assumed that the electronic apparatus 100 performs the power-saving mode immediately at the time when the electrical energy prediction command is received and then, acquires the collected electrical energy at the end of the preset period (June 30). Specifically, it is assumed that the electronic apparatus 100 performs the power-saving mode from June 11 to June 20.

Table 1511 represents the daily electrical energy consumption from June 1 to June 10.

Table 1512 represents the daily electrical energy consumption from June 11 to June 20.

Table 1513 represents the daily electrical energy consumption from June 21 to June 30.

Data 1520 represents the collected electrical energy (250 kWh) from June 1 to 30, the daily average electrical energy (8.3 kWh) from June 1 to 30, the predicted electrical energy (250 kWh) from June 1 to 30, and the target electrical energy (250 kWh) for the preset period (June 1 to 30).

The predicted electrical energy (250 kWh) for June 1 to 30 may be the predicted electrical energy calculated on June 10. The collected electrical energy (250 kWh) acquired on June 30 may be the same as the predicted electrical energy (250 kWh).

Graph 1530 represents the change in electrical energy over a day. The collected electrical energy (or cumulative power) acquired on the 30th may be 250 kWh.

The collected electrical energy (250 kWh) may refer to the cumulative electrical energy from the start time of the preset period (June 1) to the present time (June 30).

When the target electrical energy is 250 kWh, the electronic apparatus 100 may determine that the collected electrical energy does not exceed the target electrical energy (250 kWh).

FIG. 16 is a view provided to explain an operation of determining a start time of a power-saving mode to be a future time according to an embodiment of the disclosure.

Referring to FIG. 16, it is assumed that the electronic apparatus 100 does not perform the power-saving mode immediately at the time when the electrical energy prediction command is received, but instead delays performing the power-saving mode as long as possible, and then acquires the collected electrical energy at the end of the preset period (June 30). Specifically, it is assumed that the electronic apparatus 100 performs the power-saving mode from June 21 to June 30.

Table 1611 represents the daily electrical energy consumption from June 1 to June 10.

Table 1612 represents the daily electrical energy consumption from June 11 to June 20.

Table 1613 represents the daily electrical energy consumption from June 21 to June 30.

Data 1620 represents the collected electrical energy (250 kWh) from June 1 to 30, the daily average electrical energy (8.3 kWh) from June 1 to 30, the predicted electrical energy (250 kWh) from June 1 to 30, and the target electrical energy (250 kWh) for the preset period (June 1 to 30).

The predicted electrical energy (250 kWh) for June 1 to 30 may be the predicted electrical energy calculated on June 10. The collected electrical energy (250 kWh) acquired on June 30 may be the same as the predicted electrical energy (250 kWh).

Graph 1630 represents the change in electrical energy over a day. The collected electrical energy (or cumulative power) acquired on the 30th may be 250 kWh.

The collected electrical energy (250 kWh) may refer to the cumulative electrical energy from the start time of the preset period (June 1) to the present time (June 30).

When the target electrical energy is 250 kWh, the electronic apparatus 100 may determine that the collected electrical energy does not exceed the target electrical energy (250 kWh).

FIG. 17 is a view provided to explain a process of calculating a number of operating days in a power-saving mode according to an embodiment of the disclosure.

Referring to FIG. 17, it is assumed that the daily electrical energy consumption in the normal mode is 10 kWh and the daily electrical energy consumption in the power-saving mode is 5 kWh. Also, it is assumed that the target electrical energy consumption is 250 kWh. In addition, it is assumed that the preset period is 30 days.

It is assumed that the number of days in the normal mode is x, and the number of days in the power-saving mode is y.

Equation 1711 indicates that the electrical energy consumed by operating in the normal mode for the preset period (10x) and the electrical energy consumed by operating in the power-saving mode for the preset period (5y) is equal to or less than the target electrical energy (250 kWh).

Equation 1712 is an equation that organizes equation 1711 with respect to y.

Equation 1721 indicates that the sum of the number of days in the normal mode (x) and the number of days in the power-saving mode (y) is the preset period (30 days).

Equation 1723 is an equation that organizes equation 1721 with respect to y.

Graph 1730 represents equation 1712 and equation 1723.

The electronic apparatus 100 may be most efficient when consuming electrical energy close to the target electrical energy. If the electronic apparatus 100 operates in the power-saving mode for all periods, the electrical energy consumption may be low, but the electronic apparatus 100 itself may be less functional. Thus, consumer satisfaction may be low. Accordingly, the electronic apparatus 100 may reduce the number of days in the power-saving mode as much as possible without exceeding the target electrical energy.

The electronic apparatus 100 may acquire a maximum value (20) of the number of days (x) operating in the normal mode and a minimum value (10) of the number of days (y) operating in the power-saving mode based on equation 1711 and equation 1712.

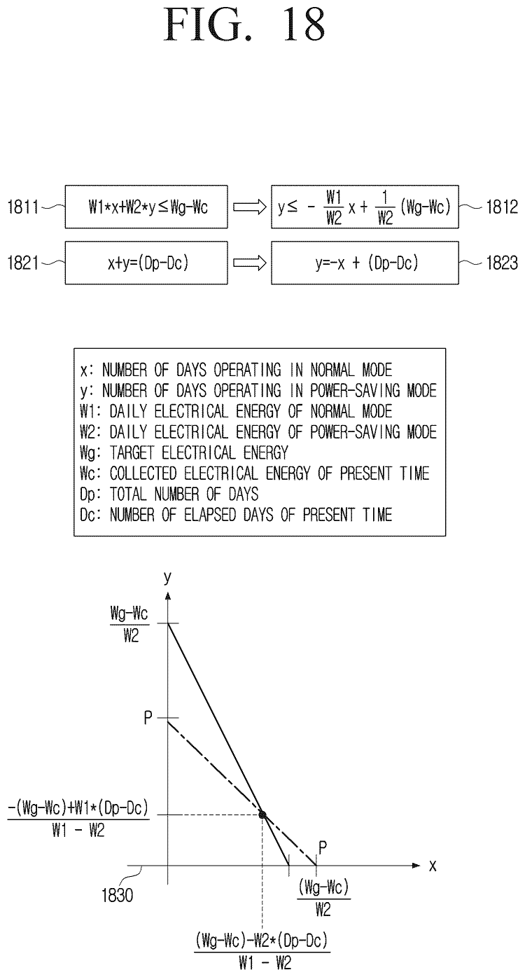

FIG. 18 is a view provided to explain a process of calculating a number of operating days in a power-saving mode according to an embodiment of the disclosure.

Referring to FIG. 18, it is assumed that the daily electrical energy consumption in the normal mode is W1 and the daily electrical energy consumption in the power-saving mode is W2. It is also assumed that the target electrical energy consumption is Wg. In addition, it is assumed that the collected electrical energy at the present time is Wc. It is also assumed that the total number of days in the preset period is Dp. Further, it is assumed that the number of elapsed days at the present time is Dc.

It is assumed that the number of days in the normal mode is x, and the number of days in the power-saving mode is y.

Equation 1811 indicates that the electrical energy consumed by operating in the normal mode for the preset period (W1*x) and the electrical energy consumed by operating in the power-saving mode for the preset period (W2*y) is equal to or less than the remaining electrical energy (Wg−Wc). The remaining electrical energy (Wg−Wc) may be the target electrical energy (Wg) minus the collected electrical energy (Wc).

Equation 1812 is an equation that organizes equation 1811 with respect to y.

Equation 1821 indicates that the sum of the number of days in the normal mode (x) and the number of days in the power-saving mode (y) is the number of remaining days (Dp-Dc). The remaining days (Dp-Dc) may be the total number of days (Dp) in the preset period minus the number of elapsed days (Dc) at the present time.

Equation 1823 is an equation that organizes equation 1821 with respect to y.

Graph 1830 represents equation 1812 and equation 1823.

The electronic apparatus 100 may acquire a maximum value ({(Wg−Wc)−W2*(Dp−Dc)}/{W1−W2}) of the number of days (x) operating in the normal mode and a minimum value ({−(Wg−Wc)+W1*(Dp−Dc)}/{W1−W2}) of the number of days (y) operating in the power-saving mode based on equation 1811 and equation 1812.

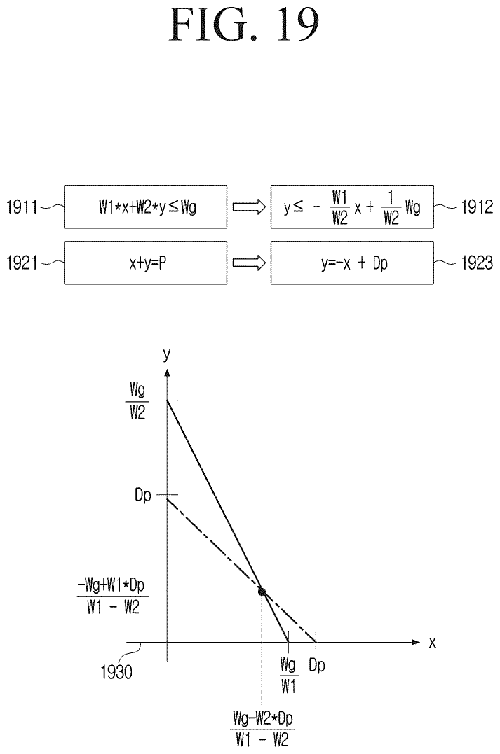

FIG. 19 is a view provided to explain a process of calculating a number of operating days a power-saving mode according to an embodiment of the disclosure.

Referring to FIG. 19, it is assumed that the daily electrical energy consumption in the normal mode is W1 and the daily electrical energy consumption in the power-saving mode is W2. It is also assumed that the target electrical energy consumption is Wg. In addition, it is assumed that the total number of days in the preset period is Dp.

It is assumed that the number of days in the normal mode is x and the number of days in the power-saving mode is y.

The embodiment of FIG. 19 may correspond to a situation where the collected electrical energy (Wc) in the embodiment of FIG. 18 is zero, and the number of elapsed days (Dc) at the present time is zero.

Equation 1911 indicates that the electrical energy consumed by operating in the normal mode for the preset period (W1*x) and the electrical energy consumed by operating in the power-saving mode for the preset period (W2*y) is equal to or less than the target electrical energy (Wg).

Equation 1912 is an equation that organizes equation 1911 with respect to y.

Equation 1921 indicates that the sum of the number of days in the normal mode (x) and the number of days in the power-saving mode (y) is the total number of days in the preset period (Dp).

Equation 1923 is an equation that organizes equation 1921 with respect to y.

Graph 1930 represents equation 1912 and equation 1923.

The electronic apparatus 100 may acquire a maximum value ({(Wg)−W2*(Dp)}/{W1−W2}) of the number of days (x) operating in the normal mode and a minimum value ({−(Wg)+W1*(Dp)}/{W1−W2}) of the number of days (y) operating in the power-saving mode based on equation 1911 and equation 1912.

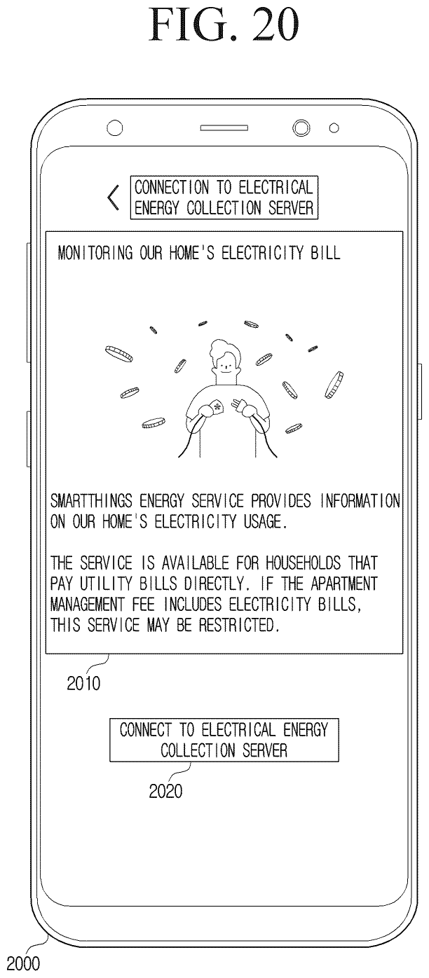

FIG. 20 is a view provided to explain a screen for acquiring electrical energy according to an embodiment of the disclosure.

Referring to FIG. 20, the electronic apparatus 100 may display a screen 2000 guiding the connection of the electrical energy collection server 220.

The screen 2000 may include at least one of a UI 2010 for displaying information related to electrical energy collection or a UI 2020 for connecting with the electrical energy collection server 220. When a user input is received via the UI 2020, the electronic apparatus 100 may acquire electrical energy related to the electronic apparatus 100 via the electrical energy collection server 220.

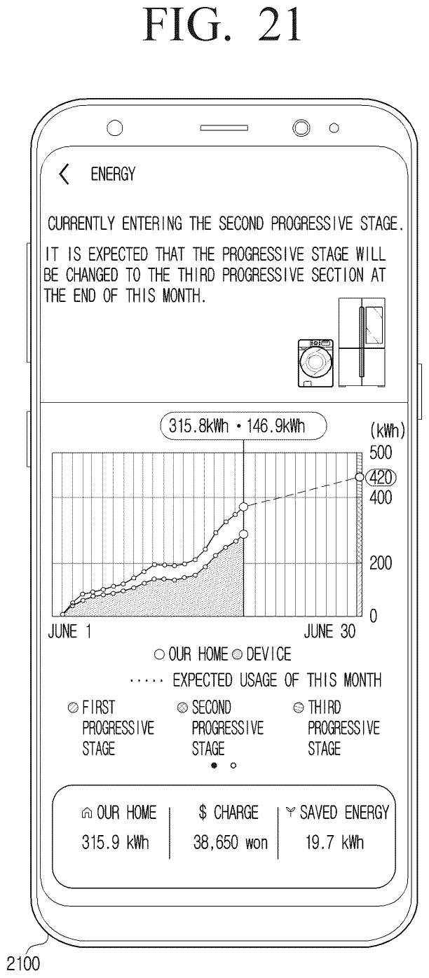

FIG. 21 is a view provided to explain a screen indicating collected electrical energy and a progressive tax section according to an embodiment of the disclosure.

Referring to FIG. 21, the electronic apparatus 100 may display a screen 2100 that displays information related to the electrical energy.

The screen 2100 may include the collected electrical energy collected at the present time during the preset period (June 1 to June 30). Here, the screen 2100 may include not only the electrical energy consumed by the electronic apparatus 100, but also the electrical energy of the entire IoT network that includes the electronic apparatus 100.

Further, the screen 2100 may include information related to a progressive tax section. Specifically, the electronic apparatus 100 may control to include at least one progressive tax section in a graph indicating the collected electrical energy. Here, the at least one progress tax section may be displayed with different colors for each section.

In addition, the screen 2100 may include at least one of the electrical energy of the entire IoT network including the electronic apparatus 100, the estimated cost of the entire IoT network including the electronic apparatus 100, and the electrical energy saved by performing the power-saving mode.

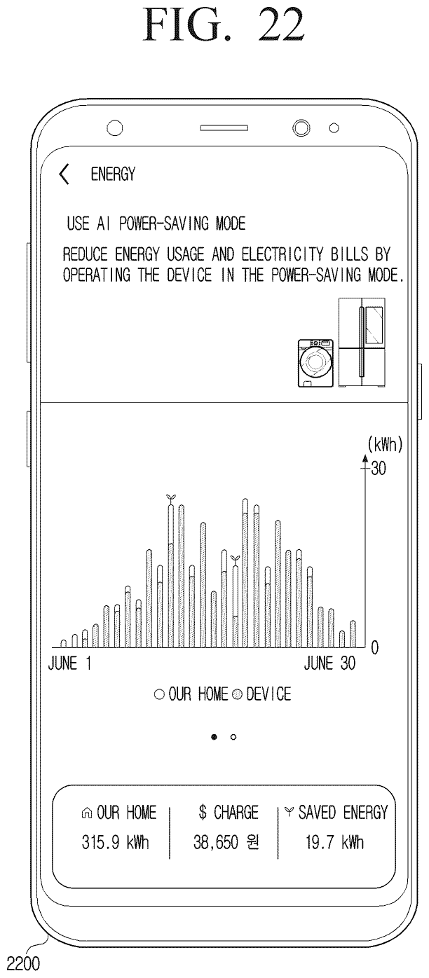

FIG. 22 is a view provided to explain a screen indicating consumed electrical energy and saved electrical energy according to an embodiment of the disclosure.

Referring to FIG. 22, the electronic apparatus 100 may display a screen 2200 indicating consumed electrical energy and saved electrical energy.

The screen 2200 may include a graph indicating the electrical energy consumed and saved by the entire IoT network including the electronic apparatus 100 for the preset period (June 1 to June 30). The consumed electrical energy and the saved electrical energy may be displayed on a daily basis. The consumed electrical energy and the saved electrical energy may be displayed as a single bar graph. The consumed electrical energy and the saved electrical energy may be displayed in different colors.

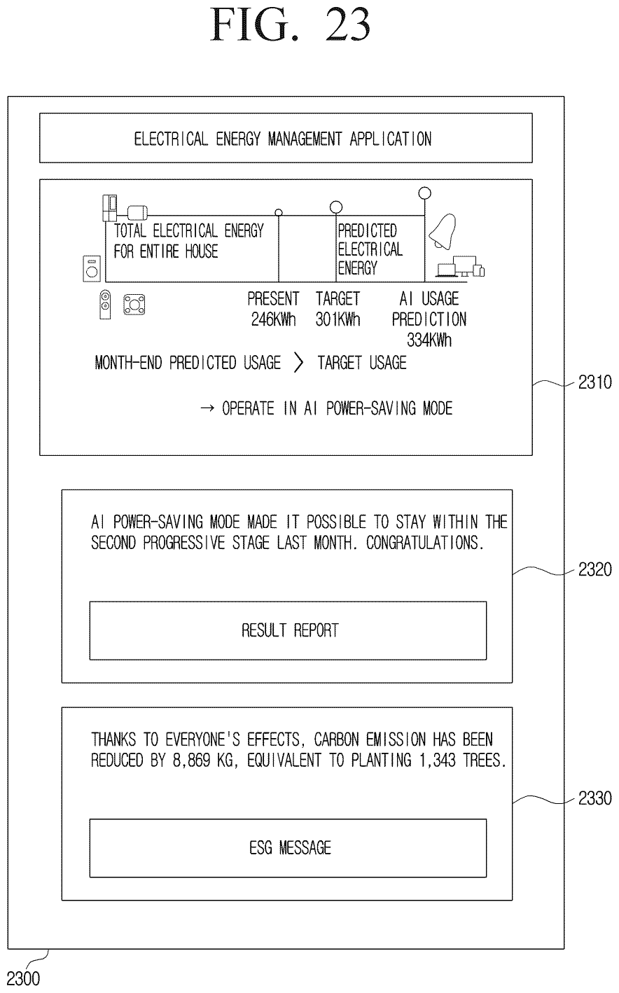

FIG. 23 is a view provided to explain a screen indicating information related to a power-saving mode according to an embodiment of the disclosure.

Referring to FIG. 23, the electronic apparatus 100 may display a screen 2300 that displays information related to the power-saving mode.

The screen 2300 may include at least one of a UI 2310 displaying the target electrical energy and the predicted electrical energy, a UI 2320 displaying an analysis result of the electrical energy consumed in a past period, or a UI 2330 displaying an analysis result of the electrical energy saved in the past period.

The UI 2310 may include the collected electrical energy, the predicted electrical energy, and the target electrical energy for the preset period based on the present time. In addition, the electronic apparatus 100 may compare the predicted electrical energy with the target electrical energy and display the result of the comparison via the UI 2310. Further, when the predicted electrical energy exceeds the target electrical energy, the electronic apparatus 100 may display text information or image information indicating that the electronic apparatus 100 is performing the power-saving mode.

The UI 2320 may include an analysis result of the consumed electrical energy in the past period. Upon receiving the user input via the UI 2320, the electronic apparatus 100 may display the analysis result of the consumed electrical energy consumed in the past period.

The UI 2330 may include an analysis result of the saved electrical energy in the past period. Upon receiving the user input via the UI 2330, the electronic apparatus 100 may display the analysis result of the saved electrical energy saved in the past period. For example, the electronic apparatus 100 may display an environmental, social and corporate governance (ESG) message based on the saved electrical energy.

FIG. 24 is a view provided to explain a screen indicating information related to a power-saving mode according to an embodiment of the disclosure.

Referring to FIG. 24, the electronic apparatus 100 may display a screen 2400 related to automatic control of the power-saving mode.

The screen 2400 includes at least one of a UI 2410 for selecting automatic control of the power-saving mode, a UI 2420 indicating that the power-saving mode is performed based on the target electrical energy, a UI 2430 indicating that a notification is provided as to whether the target is met, a UI 2440 for determining the target electrical energy, a UI 2450 for selecting a device to perform the power-saving mode, a UI 2460 for determining whether to receive a notification when the power-saving mode is performed, a UI 2470 indicating that an unconnected device does not perform the power-saving mode, a UI 2480 for indicating that the operation time may be increased when the power-saving mode is performed on a specific device, or a UI 2490 indicating that the efficiency may be reduced when the power-saving mode is performed on a specific device.

The UI 2440 for determining the target electrical energy may include at least one of an item for maximizing savings, an item for selecting a target progressive stage, or an item for entering a target rate.

Once the item for maximizing savings is selected, the electronic apparatus 100 may generate schedule information for operating in the power-saving mode for the remaining period.

When the item for selecting a target progressive stage is selected, the electronic apparatus 100 may determine the second number of operating days of the power-saving mode based on the target electrical energy corresponding to the selected progressive stage. In addition, the electronic apparatus 100 may generate schedule information based on the determined second number of operating days. Meanwhile, there may be multiple progressive stages. There may be a first progressive stage, a second progressive stage, and a third progressive stage. Each stage may have a different amount per unit of electrical energy. Each progressive stage may have minimum and maximum electrical energy. When the user selects a particular progressive stage, the electronic apparatus 100 may determine maximum electrical energy for the progressive stage selected by the user as the target electrical energy.

When the item for entering a target rate is selected, the electronic apparatus 100 may calculate target electrical energy corresponding to the entered target rate. The electronic apparatus 100 may acquire rate information corresponding to the current electrical energy. The electronic apparatus 100 may calculate the electrical energy corresponding to the target rate entered by the user. Subsequently, the electronic apparatus 100 may determine the calculated electrical energy as the target electrical energy.

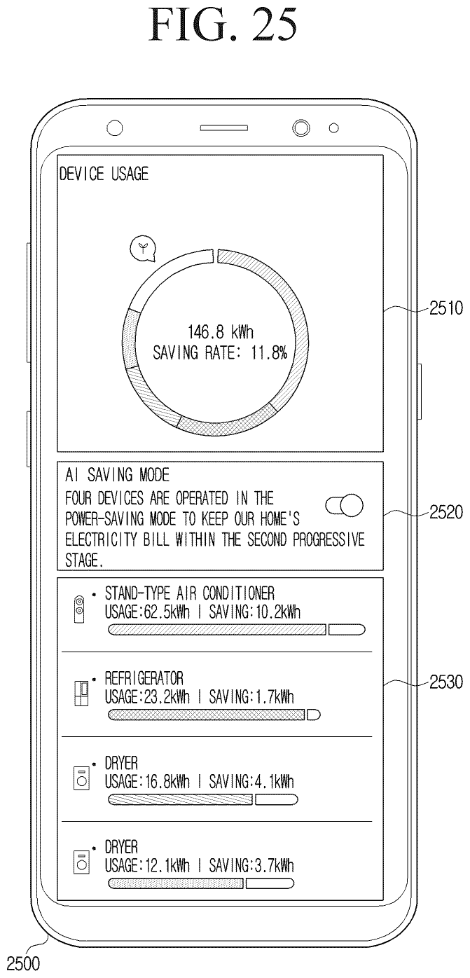

FIG. 25 is a view provided to explain a screen indicating consumed electrical energy for each device according to an embodiment of the disclosure.

Referring to FIG. 25, the electronic apparatus 100 may display a screen 2500 indicating the electrical energy of each of a plurality of devices included in the IoT network.

The screen 2500 may include at least one of a UI 2510 including a circular graph for the electrical energy of each of the plurality of devices, a UI 2520 for selecting automatic control of the power-saving mode, or a UI 2530 including a bar graph for the consumed electrical energy and the saved electrical energy of each of the plurality of devices.

The electronic apparatus 100 may display a screen 2500 that includes the electrical energy consumed by each of the plurality of devices and the electrical energy saved by each of the plurality of devices. The electronic apparatus 100 may display the consumed electrical energy and the saved electrical energy in different colors via a circular graph or a bar graph displayed on the screen 2500.

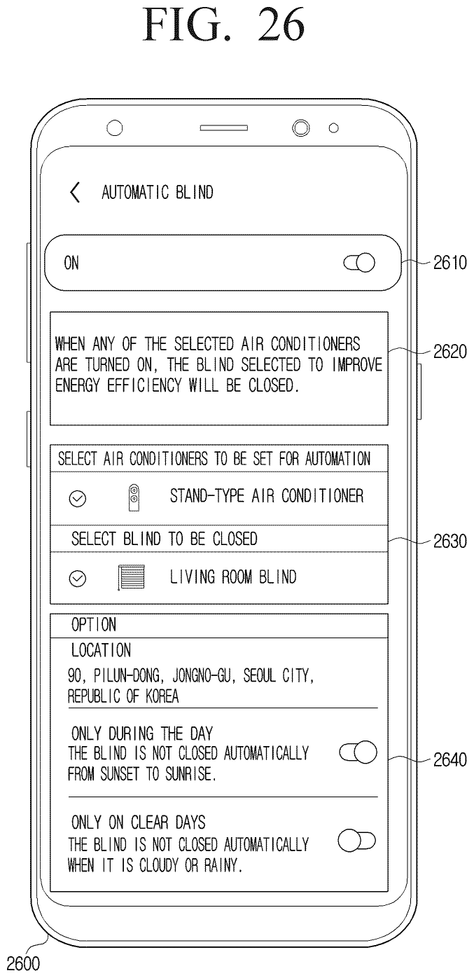

FIG. 26 is a view provided to explain a screen for a blind automatic control operation according to an embodiment of the disclosure.

Referring to FIG. 26, the electronic apparatus 100 may display an automatic blind control screen 2600.

The screen 2600 may include at least one of a UI 2610 for selecting whether to automatically control the blind, a UI 2620 indicating conditions and effects of automatically controlling the blind, a UI 2630 for selecting an automatic control device, or a UI 2640 for selecting detailed conditions related to the automatic control. The detailed conditions may be at least one of a time condition or a weather condition.

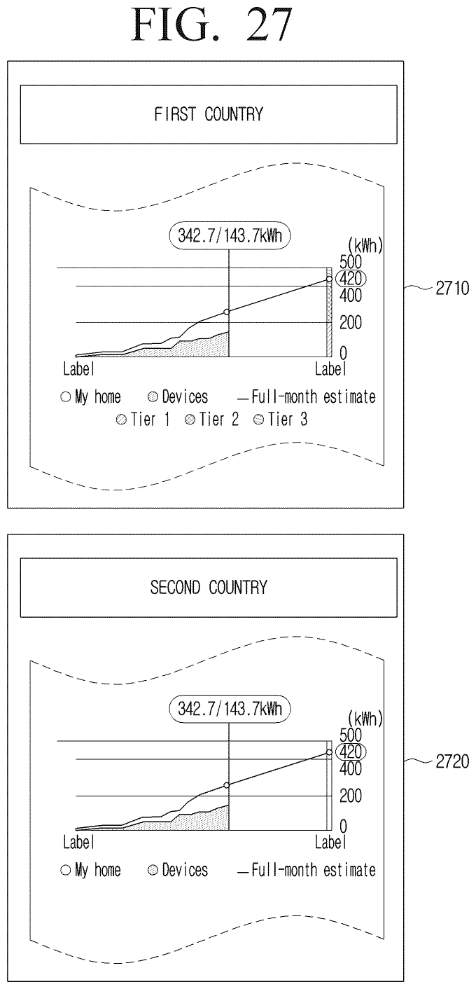

FIG. 27 is a view provided to explain that a screen indicating electrical energy varies by country according to an embodiment of the disclosure.

Referring to FIG. 27, the electronic apparatus 100 may display a graph indicating the electrical energy. It is assumed that the first country is a country in which a progressive tax section exists and the second country is a country in which a progressive tax section does not exist.

When an electrical energy management application is executed in the first country, the electronic apparatus 100 may display a screen 2710 including a graph that reflects a progressive tax section.

When the electrical energy management application is executed in the second country, the electronic apparatus 100 may display a screen 2720 including a graph that does not reflect a progressive tax section.

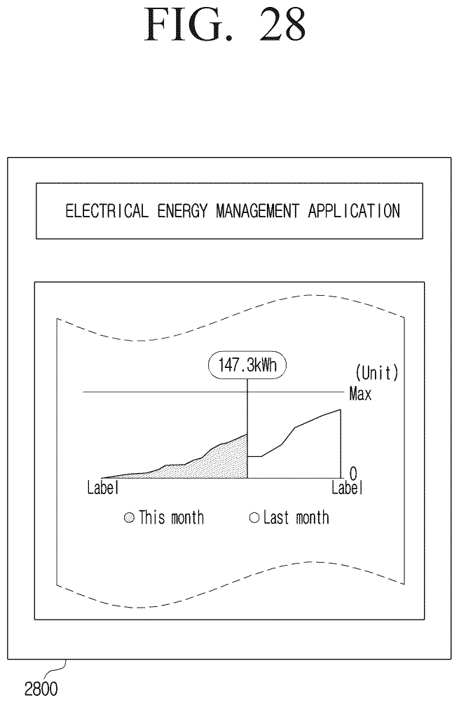

FIG. 28 is a view provided to explain a screen indicating information related to consumed electrical energy and predicted electrical energy according to an embodiment of the disclosure.

Referring to FIG. 28, the electronic apparatus 100 may display a screen 2800 comparing the electrical energy in the present period with the electrical energy in the previous period.

The screen 2800 may include a graph for comparing the electrical energy acquired in the present period with the electrical energy acquired in the previous period. The electrical energy in the present period and the electrical energy in the previous period may be displayed in different colors.

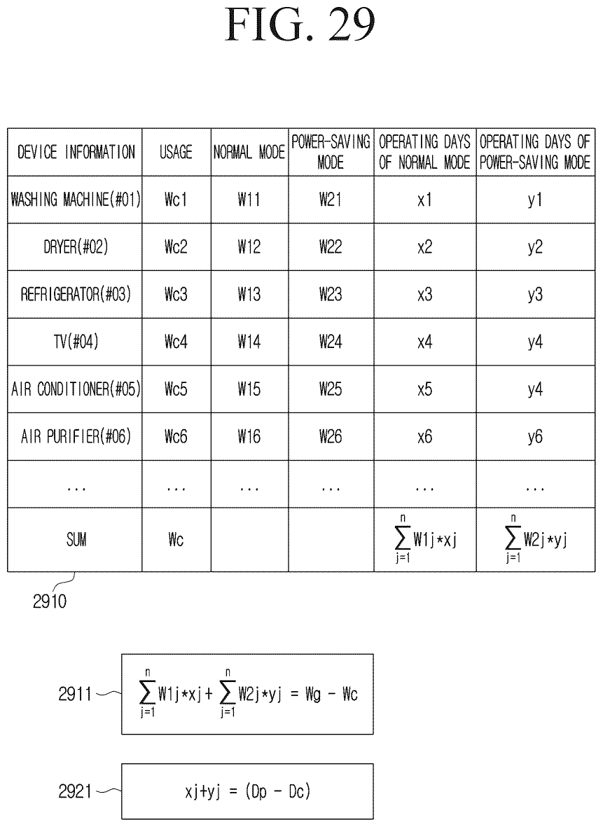

FIG. 29 is a view provided to explain an operation of performing a power-saving mode by considering electrical energy for a plurality of devices according to an embodiment of the disclosure.

Referring to FIG. 29, the electronic apparatus 100 may control a plurality of devices by taking into account the electrical energy of the plurality of devices included in the IoT network.

Table 2910 may include at least one of device information (#01 to #06) included in the IoT network, collected electrical energy (Wc1 to Wc6) of each of the devices, daily electrical energy (W11 to W16) when each of the devices is operating in the normal mode, daily electrical energy (W21 to W26) when each of the devices is operating in the power-saving mode, the number of operating days of each of the devices in the normal mode operation (x1 to x6), or the number of operating days of each of the devices in the power-saving mode operation (y1 to y6).

Equation 2911 indicates that the electrical energy (sum[W1j*xj]) consumed by the IoT network operating in the normal mode for the preset period and the electrical energy (sum [W2j*yj]) consumed by the IoT network operating in the power-saving mode for the preset period is equal to or less than the remaining electrical energy (Wg−Wc). The remaining electrical energy (Wg−Wc) may be the target electrical energy (Wg) minus the collected electrical energy (Wc).

Equation 2921 indicates that the sum of the number of days (xj) where the IoT network is operating in the normal mode and the number of days (yj) where the IoT network is operating in the power-saving mode is the “number of remaining days (Dp−Dc)”. The number of remaining days (Dp−Dc) may be the total number of days (Dp) in the preset period minus the number of elapsed days (Dc) at the present time.

The electronic apparatus 100 may acquire the number of days (xj) where each of the devices operates in the normal mode and the number of days (yj) where each of the devices operates in the power-saving mode based on equation 2911 and equation 2921.

Since the specific calculation process thereof has been described above with reference to FIG. 18, redundant description will be omitted.

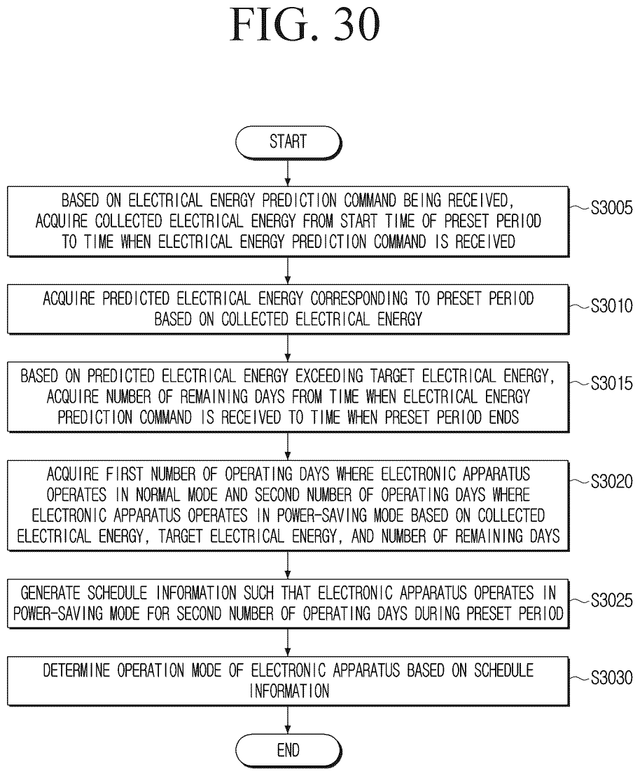

FIG. 30 is a view provided to explain a controlling method of the electronic apparatus 100 according to an embodiment of the disclosure.

Referring to FIG. 30, a controlling method of an electronic apparatus storing a preset period for measuring electrical energy includes, when an electrical energy prediction command is received, acquiring collected electrical energy from a start time of the preset period to the time when the electrical energy prediction command is received at operation S3005, acquiring predicted electrical energy corresponding to the preset period based on the collected electrical energy at operation S3010, when the predicted electrical energy exceeds target electrical energy, acquiring the number of remaining days from the time when the electrical energy prediction command is received to the time when the preset period ends at operation S3015, acquiring a first number of operating days in which the electronic apparatus operates in a normal mode and a second number of operating days in which the electronic apparatus operates in a power-saving mode based on the collected electrical energy, the target electrical energy, and the number of remaining days at operation S3020, generating schedule information such that the electronic apparatus operates in the power-saving mode for the second number of operating days during the remaining period at operation S3025, and determining an operation mode of the electronic apparatus based on the schedule information at operation S3030.

Meanwhile, the step of acquiring predicted electrical energy may include acquiring the number of elapsed days from the start time of the preset period to the time when the electrical energy prediction command is received, and acquiring the predicted electrical energy corresponding to the preset period based on the collected electrical energy, the number of elapsed days, and the total number of days of the preset period.

Meanwhile, the step of acquiring the second number of operating days may include acquiring remaining electrical energy by subtracting the collected electrical energy from the target electrical energy, acquiring daily electrical energy of the normal mode and daily electrical energy of the power-saving mode, and acquiring the second number of operating days based on the daily electrical energy of the normal mode, the daily electrical energy of the power-saving mode, the remaining electrical energy, and the number of remaining days.

Meanwhile, the step of acquiring collected electrical energy may include collecting the electrical energy for the preset period through a sensor for measuring the electrical energy, and, when the electrical energy prediction command is received, acquiring the collected electrical energy from the start time of the preset period to the time when the electrical energy prediction command is received.

Meanwhile, the controlling method may further include, when the collected electrical energy is not acquired, requesting an external server for the collected electrical energy from the start time of the preset period in an electrical energy collection server to the time when the electrical energy prediction command is received, and receiving the collected electrical energy from the external server.

Meanwhile, the controlling method may further include displaying a screen including information about a target electrical energy, and the screen may include at least one of a UI for receiving a user input related to automatic control of the power-saving mode or a UI for receiving a user input related to the target electrical energy.

Meanwhile, the UI for receiving a user input related to the target electrical energy may be a UI for selecting one of a plurality of preset progressive tax sections.

Meanwhile, the step of acquiring the first number of operating days may include subtracting the second number of operating days from the remaining period.

Meanwhile, the step of generating schedule information may include generating the schedule information such that the electronic apparatus first operates in the normal mode for the first number of operating days of the remaining period, and then operates in the power-saving mode for the second number of operating days.

Meanwhile, the collected electrical energy may be first collected electrical energy, the predicted electrical energy may be first predicted electrical energy, the number of remaining days may be the first number of remaining days, the schedule information is first schedule information, and the controlling method may include, when a second electrical energy prediction command is received, acquiring second collected electrical energy from a start time of the preset period to the time when the second electrical energy prediction command is received, acquiring second predicted electrical energy corresponding to the preset period based on the second collected electrical energy, when the second predicted electrical energy exceeds target electrical energy, acquiring the second number of remaining days from the time when the second electrical energy prediction command is received to the time when the preset period ends, changing the first schedule information to second schedule information by changing the second number of operating days based on the second collected electrical energy, the target electrical energy, and the second number of remaining days, and determining an operation mode of the electronic apparatus based on the changed second schedule information.

The controlling method of an electronic apparatus as in FIG. 30 may be executed on an electronic apparatus having the configuration of FIG. 1 or FIG. 2, and may also be executed on an electronic apparatus having other configurations.

Meanwhile, the methods according to various embodiments of the disclosure described above may be implemented in the form of an application that can be installed in the existing electronic apparatuses.

In addition, the methods according to various embodiments of the disclosure described above may be implemented by software upgrade to the existing electronic apparatuses, or by hardware upgrade alone.

Further, the various embodiments of the disclosure described above may also be performed through an embedded server provided in the electronic apparatus, or an external server of at least one of an electronic apparatus or a display device.

Meanwhile, the above-described various embodiments may be implemented as software including instructions stored in machine-readable storage media, which can be read by machine (e.g.: computer). The machine refers to a device that calls instructions stored in a storage medium, and can operate according to the called instructions, and the device may include the display device 1000 according to the aforementioned embodiments. In case an instruction is executed by a processor, the processor may perform a function corresponding to the instruction by itself, or by using other components under its control. The instruction may include a code that is generated or executed by a compiler or an interpreter. The machine-readable storage medium may be provided in the form of a non-transitory storage medium. Here, the term ‘non-transitory’ means that the storage medium is tangible without including a signal, and does not distinguish whether data are semi-permanently or temporarily stored in the storage medium.

According to an embodiment, the above-described methods according to the various embodiments may be included and provided in a computer program product. The computer program product may be traded as a product between a seller and a purchaser. The computer program product may be distributed in a form of a storage medium (e.g., a compact disc read only memory (CD-ROM)) that may be read by the machine or online through an application store (e.g., PlayStore™). In case of the online distribution, at least a portion of the computer program product may be at least temporarily stored in a storage medium such as memory of a server of a manufacturer, a server of an application store, or a relay server or be temporarily generated.

The components (e.g., modules or programs) according to various embodiments described above may include a single entity or a plurality of entities, and some of the corresponding sub-components described above may be omitted or other sub-components may be further included in the various embodiments. Alternatively or additionally, some components (e.g., modules or programs) may be integrated into one entity and perform the same or similar functions performed by each corresponding component prior to integration. Operations performed by the modules, the programs, or the other components according to the various embodiments may be executed in a sequential manner, a parallel manner, an iterative manner, or a heuristic manner, or at least some of the operations may be performed in a different order or be omitted, or other operations may be added.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device individually or collectively, cause the electronic device to perform a method of the disclosure.

Any such software may be stored in the form of volatile or non-volatile storage such as, for example, a storage device like read only memory (ROM), whether erasable or rewritable or not, or in the form of memory such as, for example, random access memory (RAM), memory chips, device or integrated circuits or on an optically or magnetically readable medium such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic apparatus comprising:
memory comprising one or more storage media storing instructions and a preset period for measuring electrical energy; and
one or more processors communicatively coupled to the memory,
wherein the instructions, when executed by the one or more processors individually or collectively, cause the electronic apparatus to:
based on an electrical energy prediction command being received, acquire collected electrical energy from a start time of a preset period to a time when the electrical energy command is received,
acquire predicted electrical energy corresponding to the preset period based on the collected electrical energy,
based on the predicted electrical energy exceeding target electrical energy, acquire a number of remaining days from a time when the electrical energy prediction command is received to a time when the preset period ends,
acquire a first number of operating days for which the electronic apparatus operates in a normal mode and a second number of operating days for which the electronic apparatus operates in a power-saving mode based on the collected electrical energy, the target electrical energy and the number of remaining days,
generate schedule information such that the electronic apparatus operates in a power-saving mode for the second operating days during the remaining period, and
determine an operation mode of the electronic apparatus based on the schedule information.

2. The apparatus of claim 1, wherein the instructions, when executed by the one or more processors individually or collectively, further cause the electronic apparatus to:
acquire a number of elapsed days from the start time of the preset period to the time when the electrical energy prediction command is received; and
acquire the predicted electrical energy corresponding to the preset period based on the collected electrical energy, the elapsed days and a total number of days in the preset period.

3. The apparatus of claim 1, wherein the instructions, when executed by the one or more processors individually or collectively, further cause the electronic apparatus to:
acquire remaining electrical energy by subtracting the collected electrical energy from the target electrical energy;
acquire daily electrical energy in a normal mode and daily electrical energy in a power-saving mode; and
acquire the second number of operating days based on the daily electrical energy in the normal mode, the daily electrical energy in the power-saving mode, and the number of remaining days.

4. The apparatus of claim 1, further comprising:
a sensor for measuring electrical energy,
wherein the instructions, when executed by the one or more processors individually or collectively, further cause the electronic apparatus to:
collect electrical energy for the preset period through the sensor, and
based on the electrical energy prediction command being received, acquire collected electrical energy from a start time of the preset period to a time when the electrical energy prediction command is received.

5. The apparatus of claim 4, further comprising:
a communication interface connected to an external server,
wherein the instructions, when executed by the one or more processors individually or collectively, further cause the electronic apparatus to:
based on the collected electrical energy not being acquired, request collected electrical energy from a start time of the preset period to a time when the electrical energy prediction command is received in from the external server through the communication interface, and
receive the collected electrical energy from the external server through the communication interface.

6. The apparatus of claim 1, further comprising:
a display,
wherein the instructions, when executed by the one or more processors individually or collectively, further cause the electronic apparatus to control the display to display a screen including information about the target electrical energy, and
wherein the screen includes at least one of a user interface (UI) for receiving a user input related to automatic control of a power-saving mode or a UI for receiving a user input related to the target electrical energy.

7. The apparatus of claim 6, wherein the UI for receiving a user input related to the target electrical energy is a UI for selecting one aggressive tax section among a plurality of preset aggressive tax sections.

8. The apparatus of claim 1, wherein the instructions, when executed by the one or more processors individually or collectively, further cause the electronic apparatus to acquire the first number of operating days by subtracting the second number of operating days from the remaining period.

9. The apparatus of claim 1, wherein the instructions, when executed by the one or more processors individually or collectively, further cause the electronic apparatus to, after operating in the normal mode first for the first number of operating days in the remaining period, generate the schedule information such that the electronic apparatus operates in the power-saving mode for the second number of operating days.

10. The apparatus of claim 1,
wherein the collected electrical energy is a first collected electrical energy,
wherein the precited electrical energy is a first predicted electrical energy,
wherein the remaining number of days is a first number of remaining days,
wherein the schedule information is first schedule information, and
wherein the instructions, when executed by the one or more processors individually or collectively, further cause the electronic apparatus to:
based on a second electrical energy prediction command being received, acquire second collected electrical energy from a start time of a preset period to a time when the second electrical energy prediction command is received,
acquire second predicted electrical energy corresponding to the preset period based on the second collected electrical energy,
based on the second predicted electrical energy exceeding the target electrical energy, acquire a second number of remaining days from a time when the second electrical energy prediction command is received to a time when the present period ends,
change the first schedule information to second schedule information by changing the second number of operating days based on the second collected electrical energy, the target electrical energy, and the second number of remaining days, and
determine an operation mode of the electronic apparatus based on the changed second schedule information.

11. A controlling method performed by an electronic apparatus that stores in memory of the electronic apparatus a preset period for measuring electrical energy, the method comprising:
based on an electrical energy prediction command being received, acquiring collected electrical energy from a start time of a preset period to a time when the electrical energy prediction command is received;
acquiring predicted electrical energy corresponding to the preset period based on the collected electrical energy;
based on the predicted electrical energy exceeding target electrical energy, acquiring a number of remaining days from a time when the electrical energy prediction command is received to a time when the preset period ends;
acquiring a first number of operating days for which the electronic apparatus operates in a normal mode and a second number of operating days for which the electronic apparatus operates in a power-saving mode based on the collected electrical energy, the target electrical energy and the number of remaining days;
generating schedule information such that the electronic apparatus operates in a power-saving mode for the second operating days during the remaining period; and
determining an operation mode of the electronic apparatus based on the schedule information.

12. The method of claim 11, wherein the acquiring of the predicted electrical energy comprises:
acquiring a number of elapsed days from a start time of the preset period to a time when the electrical energy prediction command is received; and
acquiring the predicted electrical energy corresponding to the preset period based on the collected electrical energy, the elapsed days and a total number of days in the preset period.

13. The method of claim 11, wherein the acquiring of the second number of operating days comprises:
acquiring remaining electrical energy by subtracting the collected electrical energy from the target electrical energy;
acquiring daily electrical energy in a normal mode and daily electrical energy in a power-saving mode; and
acquiring the second number of operating days based on the daily electrical energy in the normal mode, the daily electrical energy in the power-saving mode, and the number of remaining days.

14. The method of claim 11, wherein the acquiring of the collected electrical energy comprises:
collecting electrical energy for the preset period through a sensor for measuring electrical energy; and
based on the electrical energy prediction command being received, acquiring collected electrical energy from a start time of the preset period to a time when the electrical energy prediction command is received.

15. The method of claim 14, further comprising:
based on the collected electrical energy not being acquired, requesting collected electrical energy from a start time of the preset period in an electrical energy collection server to a time when the electrical energy prediction command is received from an external server; and
receiving the collected electrical energy from the external server.

16. The method of claim 11, further comprising acquiring the first number of operating days by subtracting the second number of operating days from the remaining period.

17. The method of claim 11, further comprising, after operating in the normal mode first for the first number of operating days in the remaining period, generating the schedule information such that the electronic apparatus operates in the power-saving mode for the second number of operating days.

18. The method of claim 11,
wherein the collected electrical energy is a first collected electrical energy,
wherein the precited electrical energy is a first predicted electrical energy,
wherein the remaining number of days is a first number of remaining days,
wherein the schedule information is first schedule information, and
wherein the method further comprises:
based on a second electrical energy prediction command being received, acquiring second collected electrical energy from a start time of a preset period to a time when the second electrical energy prediction command is received,
acquiring second predicted electrical energy corresponding to the preset period based on the second collected electrical energy,
based on the second predicted electrical energy exceeding the target electrical energy, acquiring a second number of remaining days from a time when the second electrical energy prediction command is received to a time when the present period ends,
changing the first schedule information to second schedule information by changing the second number of operating days based on the second collected electrical energy, the target electrical energy, and the second number of remaining days, and
determining an operation mode of the electronic apparatus based on the changed second schedule information.

19. One or more non-transitory computer-readable storage media storing one or more computer programs including computer-executable instructions that, when executed by one or more processors of an electronic apparatus individually or collectively, cause the electronic apparatus to perform operations, the operations comprising:
based on an electrical energy prediction command being received, acquiring collected electrical energy from a start time of a preset period to a time when the electrical energy prediction command is received;
acquiring predicted electrical energy corresponding to the preset period based on the collected electrical energy;
based on the predicted electrical energy exceeding target electrical energy, acquiring a number of remaining days from a time when the electrical energy prediction command is received to a time when the preset period ends;
acquiring a first number of operating days for which the electronic apparatus operates in a normal mode and a second number of operating days for which the electronic apparatus operates in a power-saving mode based on the collected electrical energy, the target electrical energy and the number of remaining days;
generating schedule information such that the electronic apparatus operates in a power-saving mode for the second operating days during the remaining period; and
determining an operation mode of the electronic apparatus based on the schedule information.

20. The one or more non-transitory computer-readable storage media of claim 19, the operations further comprising:
based on the collected electrical energy not being acquired, requesting collected electrical energy from a start time of the preset period in an electrical energy collection server to a time when the electrical energy prediction command is received from an external server; and
receiving the collected electrical energy from the external server.
